(19) United States
(12) Patent Application Publication
(10) Pub. No.: US 2015/0296646 A1
(43) Pub. Date: Oct. 15, 2015

(54) PROTECTIVE PLATE AND DISPLAY DEVICE

(71) Applicant: Sharp Kabushiki Kaisha, Osaka-shi (JP)

(72) Inventors: Masahiro Hasegawa, Osaka-shi (JP); Akira Sakai, Osaka-shi (JP); Keisuke Tsukimawashi, Osaka-shi (JP); Masayasu Fujioka, Osaka-shi (JP)

(21) Appl. No.: 14/439,261

(22) PCT Filed: Oct. 11, 2013
(86) PCT No.: PCT/JP2013/077719

§ 371 Date: Apr. 29, 2015

(30) Foreign Application Priority Data
Nov. 2, 2012 (JP) 2012-243178

(51) Int. Cl. H05K 5/03; B32B 17/06; H05K 5/00

(52) U.S. Cl. CPC H05K 5/03; H05K 5/0017; B32B 17/064; B32B 17/068; B32B 2264/102; B32B 2307/412; B32B 2457/202

(57) ABSTRACT

The invention provides a protective plate and a display device that can suppress yellowing, reduce a cost, and keep glass from scattering. The invention is a protective plate including a glass substrate; a first layer laminated on a main surface on one side of the glass substrate; a second layer laminated on the first layer; and an antireflective film pasted on a main surface on the other side of the glass substrate, in which the first layer contains polyorganosiloxane (A) and metal oxide particles (B), the second layer contains polyorganosiloxane (C), the antireflective film contains an organic matter, and transmittance of a laminated body of the glass substrate, the first layer, and the second layer is 82% or less at a wavelength of 340 nm.

### TECHNICAL FIELD

The present invention relates to a protective plate and a display device. Specifically, the invention relates to a protective plate suitable for an outdoor or semi-outdoor installation display and a display device including the same.

### BACKGROUND ART

Recently, the screen enlargement of a display device such as a liquid crystal display is in advance, so that the use as a display installed in a location such as a public place or a commercial facility (hereinafter, referred to as an “information display”) attracts attention.

In the information display, a protective plate for protecting a display portion in front (on observer side) of the display portion such as a liquid crystal display is installed in many cases. In addition, since the information display is used in a bright environment in many cases, antireflection properties are provided on the front surface and the rear surface of the protective plate, so that the visibility in the bright environment becomes good. As a base material included in the protective plate, in view of the protection of the display portion, a glass substrate is used in many cases. Also, in view of the keeping broken pieces from scattering when the glass substrate is broken, antireflective films are generally pasted respectively on the front surface and the rear surface of the glass substrate.

As a technique of providing antireflection properties to the protection plate, the following techniques are disclosed.

Disclosed is a flat display device including a pair of substrates that regulate a gas discharge space in which gas for performing discharge emission is enclosed, and including means for absorbing or reflecting infrared light (for example, see PTL 1).

In addition, disclosed is a laminated body having a layer containing polyorganosiloxane and metal oxide particles and a layer containing polyorganosiloxane (for example, see PTL 2).

Further, annual average sunshine hours of the world are disclosed (for example, see NPL 1).

### CITATION LIST

### Patent Literature

PTL 1: Japanese Unexamined Patent Application Publication No. 10-3861

PTL 2: Japanese Unexamined Patent Application Publication No. 2010-42624

### Non Patent Literature

NPL 1: “World sunshine map”, [online], [searched on Oct. 16, 2012], Internet <URL: http://earth.rice.edu/mtpe/geo/geosphere/hot/energyfuture/Sunlight.html>

### SUMMARY OF INVENTION

### Technical Problem

However, if a protective plate obtained by pasting antireflective films on both sides of glass is used in a location exposed to the sunlight, the color of the protective plate may be changed to yellow (yellowing).

FIG. 14 is a cross-sectional view schematically illustrating a display device of Comparative Form 1 reviewed by the inventors of the invention.

As illustrated in FIG. 14, the display device of Comparative Form 1 includes a display portion 108 and a protective plate 102 arranged in front of the display portion 108. The protective plate 102 includes a glass substrate 103 and antireflective films 106 and 109 pasted respectively on the front and rear surfaces of the glass substrate 103. The antireflective films 106 and 109 are general antireflective films, and are manufactured by coating an organic material on a base film and forming antireflective layers. As the material of the base film, an organic material such as polyethylene terephthalate (PET) or triacetylcellulose (TAC) is used. Since the antireflective films 106 and 109 are manufactured by a coating method, the antireflective films 106 and 109 can be manufactured with comparatively low cost. In addition, since they are films, they also have a function as a film keeping broken pieces of glass from scattering. However, the base film and the antireflective layers are manufactured by an organic material, they are weak on ultraviolet light and if the antireflective films 106 and 109 are used at a location exposed to the sunlight, the antireflective films 106 and 109 become yellow. The organic matter contained in the base film and the antireflective layer has a carbon-carbon bond (C—C bond), and the wavelength corresponding to the dissociation energy is approximately 340 nm. Therefore, if the antireflective films 106 and 109 are exposed to ultraviolet light, they absorb ultraviolet light, the carbon-carbon bond is broken, and thus the antireflective films 106 and 109 become yellow.

FIG. 15 is a cross-sectional view schematically illustrating a display device of Comparative Form 2 reviewed by the inventors of the invention.

As illustrated in FIG. 15, the display device of Comparative Form 2 includes a display portion 208 and a protective plate 202 arranged in front of the display portion 208. The protective plate 202 includes a glass substrate 203 and antireflective layers 206 and 209 formed respectively on the front and rear surfaces of the glass substrate 203. The antireflective layers 206 and 209 are formed by depositing metal oxide on the glass substrate 203 by a vacuum deposition method. The display device of Comparative Form 2 uses the technique disclosed in PTL 1. Since the antireflective layers 206 and 209 are formed by an inorganic material, they are strong on ultraviolet light, and the protective plate 202 is suitably used at a location exposed to the sunlight. However, since the antireflective layers 206 and 209 are formed by the vacuum deposition method, the cost of the protective plate 202 is very high. In addition, since the antireflective layers 206 and 209 are formed directly on the glass substrate 203, the protective plate 202 does not contain a member that keeps broken pieces of glass from scattering and is dangerous.

FIG. 16 is a cross-sectional view schematically illustrating a display device of Comparative Form 3 reviewed by the inventors of the invention.

As illustrated in FIG. 16, the display device of Comparative Form 3 includes a display portion 308 and a protective plate 302 arranged in front of the display portion 308. The protective plate 302 includes a glass substrate 303, an antireflective layer 309 is formed on the front surface of the glass substrate 303 with an inorganic material in the same manner as in the antireflective layer 209 described above, and an antireflective film 306 is pasted on the rear surface of the glass substrate 303 in the same manner as in the antireflective films 106 and 109 described above. That is, the protective plate 302 includes the inorganic antireflective layer 309 which is strong on the sunlight and the antireflective film 306 having the antiscattering function. The cost of the protective plate 302 is low compared with the protective plate 202 of Comparative Form 2, but the antireflective layer 309 is formed by the vacuum deposition method, and the cost of the protective plate 302 is also high.

FIG. 17 is a cross-sectional view schematically illustrating a display device of Comparative Form 4 reviewed by the inventors of the invention.

As illustrated in FIG. 17, the display device of Comparative Form 4 includes a display portion 408 and a protective plate 402 arranged in front of the display portion 408. The protective plate 402 includes a glass substrate 403, a hard coat layer 404 formed on the front surface of the glass substrate 403, and an antireflective layer 405 formed on the hard coat layer 404. The hard coat layer 404 is formed by coating a composition obtained by mixing metal oxide particles with polyorganosiloxane on the glass substrate 403, and the antireflective layer 405 is formed by coating a composition obtained by mixing silica particles with polyorganosiloxane on the hard coat layer 404. The display device of Comparative Form 4 uses the technique disclosed in PTL 2. Polyorganosiloxane is an organic-inorganic hybrid material obtained by bonding an organic functional group to a main chain having a siloxane bond (Si—O bond), and is strong on ultraviolet light. In addition, if the composition described above is used, a film can be formed by a coating method. However, since polyorganosiloxane has high transmittance in an ultraviolet area, components of the display portion 408 may be deteriorated depending on the transmittance of the glass substrate 403. For example, if the liquid crystal display is used as the display portion 408, members such as an antireflective film, a hard coat layer, and a polarizing plate included in the liquid crystal display may be deteriorated. In addition, since the hard coat layer 404 and the antireflective layer 405 are directly formed on the glass substrate 403, the protective plate 402 does not contain a member that keeps broken pieces of glass from scattering and is dangerous.

FIG. 18 is a cross-sectional view schematically illustrating a display device of Comparative Form 5 reviewed by the inventors of the invention.

As illustrated in FIG. 18, the display device of Comparative Form 5 includes a display portion 508 and a protective plate 502 arranged in front of the display portion 508. The protective plate 502 is the same as the protective plate 402 of Comparative Form 4 except for an antireflective film 506 pasted on the rear surface of the glass substrate 403 in the same manner as in the antireflective films 106 and 109 described above. Since the protective plate 502 includes the antireflective film 506, it exhibits the antiscattering function. However, as described above, since polyorganosiloxane has high transmittance in the ultraviolet area, the antireflective film 506 may become yellow depending on the transmittance of the glass substrate 403.

The invention is conceived in view of the phenomenon described above, and an advantage of the invention is to provide a protective plate and a display device that can suppress yellowing, reduce the cost, and keep broken pieces of glass from scattering.

### Solution to Problem

An aspect of the invention may be a protective plate including a glass substrate; a first layer laminated on a main surface on one side of the glass substrate; a second layer laminated on the first layer; and an antireflective film pasted on a main surface on the other side of the glass substrate, the first layer may contain polyorganosiloxane (A) and metal oxide particles (B), the second layer may contain polyorganosiloxane (C), the antireflective film may contain an organic matter, and transmittance of a laminated body of the glass substrate, the first layer, and the second layer may be 82% or less at a wavelength of 340 nm.

Hereinafter, the protective plate is also referred to as a protective plate according to the invention.

The preferred embodiments of the protective plate according to the invention are described below. In addition, the preferred embodiments described below may be appropriately combined with each other, and an embodiment obtained by combining two or more preferred embodiments is one of the preferred embodiments.

The first layer may be obtainable from a cured product of a composition (I),

the composition (I) may contain at least one kind of silane compound (a1) selected from the group consisting of at least one kind of organosilane expressed by Expression (1) below, a hydrolysate of the organosilane, and a condensate of the organosilane, and metal oxide particles (B)

R¹ₙSi(OR²)₄₋ₙ (1)

(in the expression, R¹ represents a 1-8C univalent organic group, and if there are two R¹s, the R¹s may be the same with or different from each other. R² independently represents a 1-5C alkyl group or a 1-6C acyl group. n is an integer of 0 to 2.),

the second layer may be obtainable from a cured product of a composition (II), and

the composition (II) may contain at least one kind of silane compound (c1) selected from the group consisting of at least one kind of organosilane expressed by Expression (2), a hydrolysate of the organosilane, and a condensate of the organosilane.

R³ₘSi(OR⁴)₄₋ₘ (2)

(in the expression, R³ respresents a 1-8C univalent organic group, if there are two R³s, the R³s may be the same with or different from each other. R⁴ independently represents a 1-5C alkyl group or a 1-6C acyl group. m is an integer of 0 to 2.).

The composition (I) may contain the polymer (A1) and the metal oxide particles (B), and

the polymer (A1) may be obtainable by performing hydrolysis and condensation on the silane compound (a1) and a vinyl-based polymer (a2) containing a silyl group having a silicon atom bonded to a hydrolyzable group and/or a hydroxyl group.

The composition (II) may contain a polymer (C1), and

the polymer (C1) may be obtainable by performing hydrolysis and condensation on the silane compound (c1) and the vinyl-based polymer (c2) containing a silyl group having a silicon atom bonded to a hydrolyzable group and/or a hydroxyl group.

The composition (II) may further contain silica particles (D).

The glass substrate may contain soda glass or alkali free glass.

The antireflective film may contain a TAC film.

The antireflective film may contain a base film with an ultraviolet light absorber.

Another aspect of the invention may be a display device including the protective plate according to the invention.

### Advantageous Effects of Invention

According to the invention, a protective plate and a display device that can suppress yellowing, reduce the cost, and keep broken pieces of glass from scattering can be realized.

### BRIEF DESCRIPTION OF DRAWINGS

FIG. 1 is a cross-sectional view schematically illustrating a protective plate and a display device according to an embodiment of the invention.

FIG. 2 is a cross-sectional view schematically illustrating a protective plate of Example 1.

FIG. 3 is a cross-sectional view schematically illustrating a protective plate of Comparative Example 1.

FIG. 4 is a cross-sectional view schematically illustrating a protective plate of Comparative Example 2.

FIG. 5 is a graph illustrating transmittance of protective glass used in Example 1 and Comparative Example 1 and transmittance of a soda glass plate used in Comparative Example 2.

FIG. 6 is a cross-sectional view schematically illustrating a protective plate of Example 2.

FIG. 7 is a graph illustrating transmittance of protective glass used in Example 2 and transmittance of an alkali free glass plate used in Example 2.

FIG. 8 is a graph illustrating a result obtained by measuring transmittance of the protective plate of Example 1 before and after an ultraviolet light irradiation test.

FIG. 9 is a graph illustrating a result obtained by measuring transmittance of the protective plate of Example 2 before and after an ultraviolet light irradiation test.

FIG. 10 is a graph illustrating a result obtained by measuring transmittance of the protective plate of Comparative Example 1 before and after an ultraviolet light irradiation test.

FIG. 11 is a graph illustrating a result obtained by measuring transmittance of the protective plate of Comparative Example 2 before and after an ultraviolet light irradiation test.

FIG. 12 is a cross-sectional view schematically illustrating a display device of Example 3.

FIG. 13 is a cross-sectional view schematically illustrating a display device of Comparative Example 3.

FIG. 14 is a cross-sectional view schematically illustrating a display device of Comparative Form 1.

FIG. 15 is a cross-sectional view schematically illustrating a display device of Comparative Form 2.

FIG. 16 is a cross-sectional view schematically illustrating a display device of Comparative Form 3.

FIG. 17 is a cross-sectional view schematically illustrating a display device of Comparative Form 4.

FIG. 18 is a cross-sectional view schematically illustrating a display device of Comparative Form 5.

FIG. 19 is a graph illustrating transmittance of an antireflective film used in Example 1.

FIG. 20 is a graph illustrating transmittance of a TAC film that does not contain an ultraviolet light absorber.

FIG. 21 is a graph illustrating transmittance of a TAC film with an ultraviolet light absorber contained in the antireflective film used in Example 1.

### DESCRIPTION OF EMBODIMENTS

The invention is described in detail with reference to the embodiments and the drawings, but the invention is not limited to the embodiments.

In the specification, “polyorganosiloxane” refers to a polymer having a Si—O bond as a skeleton.

In addition, in the specification, the “front surface” refers to a main surface close to the observer, and the “rear surface” refers to a main surface far from the observer.

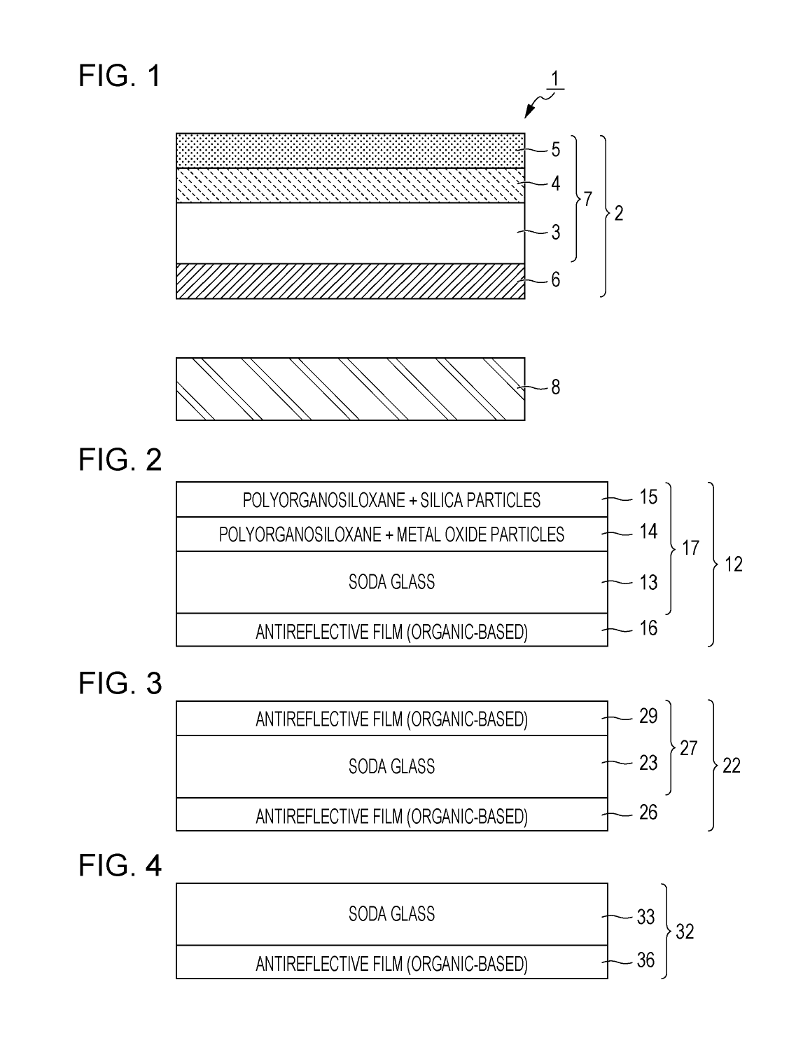

FIG. 1 is a cross-sectional view schematically illustrating a protective plate and a display device according to an embodiment of the invention.

As illustrated in FIG. 1, a protective plate 2 according to the embodiment includes a glass substrate 3, a first layer 4 laminated on the main surface (front surface) on one side of the glass substrate 3, a second layer 5 laminated on the first layer 4, and an antireflective film 6 pasted on the main surface (rear surface) on the other side of the glass substrate 3, the first layer 4 contains polyorganosiloxane (A) and metal oxide particles (B), the second layer 5 contains polyorganosiloxane (C), the antireflective film 6 contains an organic matter, and transmittance of a laminated body 7 of the glass substrate 3, the first layer 4, and the second layer 5 is 82% or less, and more preferably 81% or less at a wavelength of 340 nm.

The first layer 4 and the second layer 5 are arranged on the front surface of the glass substrate 3 according to the embodiment, and antireflection properties are shown. In addition, the antireflective film 6 is arranged on the rear surface of the glass substrate 3. Accordingly, the protective plate 2 can reduce the reflection on the front surface and the rear surface.

In addition, since the first layer 4 and the second layer 5 all are strong on ultraviolet light, and have excellent weather resistance, the yellowing of the front surface of the protective plate 2 can be suppressed. Meanwhile, since the antireflective film 6 contains an organic matter, the antireflective film 6 may not be strong on ultraviolet light. It is considered that this is because the wavelength corresponding to the bond dissociation energy of a carbon-carbon bond (C—C bond) contained in the organic matter is approximately 340 nm. Accordingly, according to the embodiment, the transmittance of the laminated body of the glass substrate 3, the first layer 4, and the second layer 5 at a wavelength of 340 nm is adjusted to be 82% or less (preferably, 81% or less), so that the strength of the ultraviolet light incident on the antireflective film 6 is caused to be weak. Therefore, the yellowing of the antireflective film 6 caused by ultraviolet light can be suppressed. As a result, even if the protective plate 2 is used in a location exposed to the sunlight, the yellowing of the protective plate 2 by the ultraviolet light can be suppressed.

Further, the first layer 4 and the second layer 5 all can be formed by a coating method, and the antireflective film 6 also can be manufactured by a coating method. Accordingly, the cost of the protective plate 2 can be reduced.

Also, since the protective plate 2 includes the antireflective film 6 on the rear surface of the glass substrate 3, even if the glass substrate 3 is broken, broken pieces thereof can be effectively kept from scattering.

Hereinafter, respective configurations of the protective plate according to the embodiment are described in detail.

### (1) Glass Substrate

The glass substrate used in the protective plate of the embodiment is a substrate formed of glass, and the kind (composition) of the glass is not particularly limited. Specific examples of the glass include soda glass, alkali free glass, and quartz glass. The thickness of the glass substrate is preferably in the range of 0.5 mm to 5 mm. If the thickness is less than 0.5 mm, the protective plate may be bent, and if the thickness is greater than 5 mm, the weight of the display device may increase.

### (2) First Layer

The first layer includes the polyorganosiloxane (A) and the metal oxide particles (B). Depending on the use thereof, the first layer having the refractive index which is equal to or greater than 1.50 and less than 1.85 is used, and the first layer having the thickness in the range of 0.01 μm to 10 μm is used.

### (2-1) Composition (I)

The first layer is obtainable from a cured product containing at least one kind of silane compound (a1) selected from the group consisting of at least one kind of organosilane (hereinafter, referred to as “organosilane (1)”) expressed by Expression (1) below, a hydrolysate of the organosilane (1), and a condensate of the organosilane (1), and the metal oxide particles (B) (hereinafter, referred to as “composition (I)”).

R¹ₙSi(OR²)₄₋ₙ (1)

(in the expression, R¹ represents a 1-8C univalent organic group, and if there are two R¹s, the R¹s may be the same with or different from each other. R² independently represents a 1-5C alkyl group or a 1-6C acyl group. n is an integer of 0 to 2.)
(Silane Compound (a1))

The silane compound (a1) according to the embodiment is at least one kind of silane compound selected from the group consisting of organosilane (1) expressed by Expression (1) above, a hydrolysate of the organosilane (1), and a condensate of the organosilane (1), and among the three kinds of silane compounds, not only one kind of silane compound may be used, arbitrarily two kinds of silane compounds may be used in mixture, or all three kinds of silane compounds may be used in mixture. In addition, if the organosilane (1) is used as the silane compound (a1), one kind of the organosilane (1) may be used singly, or two or more kinds thereof may be used in combination. In addition, the hydrolysate and the condensate of the organosilane (1) may be formed of one kind of organosilane (1), or may be formed of two or more kinds of organosilane (1) in combination.

The hydrolysate of the organosilane (1) may be obtained by hydrolyzing at least one of 2 to 4 OR² groups contained in the organosilane (1). For example, the hydrolysate of the organosilane (1) may be one obtained by hydrolyzing one OR² group, one obtained by hydrolyzing two or more OR² groups, or the mixture thereof.

The condensate of the organosilane (1) is obtained by condensing a silanol group in the hydrolysate generated by hydrolyzing the organosilane (1) and thus forming the Si—O—Si bond. In the embodiment, all silanol groups do not have to be condensed, and the condensate may include one obtained by condensing a portion of the silanol group, one obtained by condensing most (including all) silanol groups, and further the mixture thereof.

In Expression (1), R¹ is a 1-8C univalent organic group, and specific examples thereof include an alkyl group such as a methyl group, an ethyl group, an n-propyl group, an i-propyl group, an n-butyl group, an i-butyl group, a sec-butyl group, a t-butyl group, an n-hexyl group, an n-heptyl group, an n-octyl group, and a 2-ethylhexyl group; an acyl group such as an acetyl group, a propionyl group, a butyryl group, a valeryl group, a benzoyl group, a trioyl group, and a caproyl group;

a vinyl group, an allyl group, a cyclohexyl group, a phenyl group, an epoxy group, a glycidyl group, a (meth)acryloxy group, a ureido group, an amide group, a fluoroacetamide group, and an isocyanate group.

Further, as R¹, substituted derivatives of the organic groups may be included. Examples of the substituted group of the substituted derivative of R¹ include a halogen atom, a substituted or non-substituted amino group, a hydroxyl group, a mercapto group, an isocyanate group, a glycidoxy group, a 3,4-epoxycyclohexyl group, a (meth)acryloxy group, a ureido group, and an ammonium salt group. However, the number of carbon atoms of R¹ formed of these substituted derivatives is preferably 8 or less including carbon atoms in a substituted group. If plural R¹s exist in Expression (1), the R¹s may be the same with or different from each other.

Examples of R² which is a 1-5C alkyl group include a methyl group, an ethyl group, an n-propyl group, an i-propyl group, an n-butyl group, a sec-butyl group, a t-butyl group, and an n-pentyl group, and examples of R² which is a 1-6C acyl group include an acetyl group, a propionyl group, a butyryl group, a valeryl group, and a caproyl group. If plural R²s exist in Expression (1), the R²s may be the same with or different from each other.

Specific examples of the organosilane (1) include tetraalkoxysilanes such as tetramethoxysilane, tetraethoxysilane, tetra-n-propoxysilane, tetra-i-propoxysilane, and tetra-n-butoxysilane (n=0 in Expression (1));

trialkoxysilanes such as methyltrimethoxysilane, methyltriethoxysilane, ethyltrimethoxysilane, ethyltriethoxysilane, n-propyltrimethoxysilane, n-propyltriethoxysilane, i-propyltrimethoxysilane, i-propyltriethoxysilane, n-butyltrimethoxysilane, n-butyltriethoxysilane, n-pentyltrimethoxysilane, n-hexyltrimethoxysilane, n-heptyltrimethoxysilane, n-octyltrimethoxysilane, vinyltrimethoxysilane, vinyltriethoxysilane, cyclohexyltrimethoxysilane, cyclohexyltriethoxysilane, phenyltrimethoxysilane, phenyltriethoxysilane, 3-chloropropyltrimethoxysilane, 3-chloropropyltriethoxysilane, 3,3,3-trifluoropropyltrimethoxysilane, 3,3,3-trifluoropropyltriethoxysilane, 3-aminopropyltrimethoxysilane, 3-aminopropyltriethoxysilane, 2-hydroxyethyl-trimethoxysilane, 2-hydroxyethyltriethoxysilane, 2-hydroxypropyltrimethoxysilane, 2-hydroxypropyltriethoxysilane, 3-hydroxypropyltrimethoxysilane, 3-hydroxypropyltriethoxysilane, 3-mercaptopropyltrimethoxysilane, 3-mercaptopropyltriethoxysilane, 3-isocyanatopropyltrimethoxysilane, 3-isocyanatopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, 3-(meth)acryloxypropyltrimethoxysilane, 3-(meth)acryloxypropyltriethoxysilane, 3-ureidopropyltrimethoxysilane, and 3-ureidopropyltriethoxysilane (n=1 in Expression (1));

dialkoxysilanes such as dimethyldimethoxysilane, dimethyldiethoxysilane, diethyldimethoxysilane, diethyldiethoxysilane, di-n-propyldimethoxysilane, di-n-propyldiethoxysilane, di-i-propyldimethoxysilane, di-i-propyldiethoxysilane, di-n-butyldimethoxysilane, di-n-butyldiethoxysilane, di-n-pentyldimethoxysilane, di-n-pentyldiethoxysilane, di-n-hexyldimethoxysilane, di-n-hexyldiethoxysilane, di-n-heptyldimethoxysilane, di-n-heptyldiethoxysilane, di-n-octyldimethoxysilane, di-n-octyldiethoxysilane, di-n-cyclohexyldimethoxysilane, di-n-cyclohexyldiethoxysilane, diphenyldimethoxysilane, and diphenyldiethoxysilane (n=2 in Expression (1));

methyltriacetyloxysilane (n=1 in Expression (1)), and dimethyldiacetyloxysilane (n=2 in Expression (1)).

Among them, trifunctional organosilane in which n=1 in Expression (1) is mainly used. In view of stability of the silane compound (a1) according to the embodiment, the trifunctional organosilane may be used in combination with bifunctional organosilane in which n=2 in Expression (1). As the trifunctional organosilane, trialkoxysilanes are particularly preferable, and as the bifunctional organosilane, dialkoxysilanes are preferable.

If the trifunctional organosilane and the bifunctional organosilane are used in combination, the weight ratio of the trifunctional organosilane/bifunctional organosilane respectively in terms of completely hydrolyzed and condensed products is preferably in the range of 95/5 to 10/90, more preferably in the range of 90/10 to 30/70, and particularly preferably in the range of 85/15 to 40/60. However, the sum of the trifunctional organosilane and the bifunctional organosilane (in terms of completely hydrolyzed and condensed products) is 100. If the content of the trifunctional organosilane is too much, the preservation stability of the composition (I) may be deteriorated. If the content of the trifunctional organosilane is too small, curing properties of the cured body may be deteriorated. In addition, in the specification, the completely hydrolyzed and condensed product refers to a product in which 100% of an —OR group of the silane compound is hydrolyzed to become a SiOH group, and is completely condensed to become a siloxane structure.

In the embodiment, as the silane compound (a1), one type of organosilane (1) may be used singly, and two or more types of the organosilane (1) may be used in combination. If two or more types of organosilane (1) used as the silane compound (a1) are averaged and shown in Expression (1) above, the averaged n (hereinafter, referred to as an “average value of n”) is preferably in the range of 0.5 to 1.9, more preferably in the range of 0.6 to 1.7, and particularly preferably in the range of 0.7 to 1.5. If the average value of n is less than the lower limit, the preservation stability of the composition (I) may be deteriorated. If the average value of n is greater than the upper limit, the curing properties of the cured body (coated film) may be deteriorated.

The average value of n can be adjusted to the range described above, by appropriately using bifunctional to tetrafunctional organosilane (1) in combination, and appropriately adjusting the combination ratio thereof.

In addition, this is the same when the hydrolysate or the condensate of the organosilane (1) is used as the silane compound (a1).

In the embodiment, as the silane compound (a1), the organosilane (1) may be used as it is, but the hydrolysate and/or the condensate of the organosilane (1) can be used. If the hydrolysate and/or the condensate of the organosilane (1) is used, a product obtained by hydrolyzing and condensing the organosilane (1) in advance may be used. However, when the composition (I) is prepared, the hydrolysate and/or the condensate of the organosilane (1) may be prepared by hydrolyzing and condensing the organosilane (1).

The weight average molecular weight (hereinafter, presented as “Mw”) of the condensate of the organosilane (1) in terms of polystyrene, which is measured by a gel permeation chromatography method (GPC method) is preferably in the range of 300 to 100,000, and more preferably in the range of 500 to 50,000.

If the condensate of the organosilane (1) is used as the silane compound (a1) according to the embodiment, the condensate may be prepared with the organosilane (1), or the commercially available condensate of the organosilane may be used. Examples of the commercially available condensate of the organosilane include MKC silicate manufactured by Mitsubishi Chemical Corporation, ethyl silicate manufactured by Colcoat Co., Ltd., a silicone resin or a silicone oligomer manufactured by Dow Corning Toray Co., Ltd., a silicone resin or a silicone oligomer manufactured by Momentive Performance Materials Inc., a silicone resin or a silicone oligomer manufactured by Shin-Etsu Chemical Co., Ltd., and hydroxyl group-containing polydimethylsiloxane manufactured by Dow Corning Asia. The commercially available condensate of the organosilane may be used as it is, or may be further condensed to be used.

### (Polymer A1)

In the embodiment, as the composition (I), a product containing the polymer (A1) prepared by performing a hydrolyzation and condensation reaction between the silane compound (a1) and a vinyl-based polymer (a2) containing a specific silyl group and the metal oxide particles (B) may be used. More specifically, the polymer (A1) is prepared by adding a catalyst that accelerates the hydrolyzation and condensation reaction and water to a mixture containing the silane compound (a1) and the vinyl-based polymer (a2) containing the silyl group.

### (Silyl Group-Containing Vinyl-Based Polymer (A2))

The vinyl-based polymer (a2) containing the specific silyl group used in the embodiment (hereinafter, referred to as “specific silyl group-containing vinyl-based polymer (a2)”) contains a silyl group having a silicon atom obtained by bonding the hydrolyzable group and/or the hydroxyl group (hereinafter, referred to as “specific silyl group”). The specific silyl group-containing vinyl-based polymer (a2) preferably has a specific silyl group at a terminal and/or a side chain of a polymer molecular chain.

The polymer (A1) is formed by co-condensing the hydrolyzable group and/or hydroxyl group in the specific silyl group with the silane compound (a1). A layer obtained by coating the composition containing the polymer (A1) and the metal oxide particles (B) on the surface of the glass substrate functions as a high refractive index layer, and a product obtained by further coating a second layer described below can be used as an antireflective laminated body.

The content of the specific silyl group in the specific silyl group-containing vinyl-based polymer (a2) in terms of the amount of the silicon atom is generally in the range of 0.1% by weight to 2% by weight, and preferably in the range of 0.3% by weight to 1.7% by weight with respect to the polymer before the specific silyl group is introduced. If the content of the specific silyl group in the specific silyl group-containing vinyl-based polymer (a2) is less than the lower limit, a bonding portion shared with the silane compound (a1) or a remaining specific silyl group becomes small so that the required strength of the coated layer may not be obtained. Meanwhile, if the content is greater than the upper limit, gelation may occur when the composition is preserved.

### (Specific Silyl Group)

The specific silyl group is preferably a group expressed by Expression (3) below.

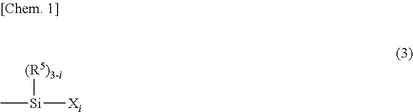

(in the expression, X represents a hydrolyzable group such as a halogen atom, an alkoxyl group, an acetoxy group, a phenoxy group, a thioalkoxyl group, and an amino group, or a hydroxyl group, R⁵ represents a hydrogen atom, a 1-10C alkyl group, or a 1-10C aralkyl group, and i represents an integer of 1 to 3.)

(Method of Manufacturing Specific Silyl Group-Containing Vinyl-Based Polymer (a2))

This specific silyl group-containing vinyl-based polymer (a2) can be manufactured, for example, by a method of (I) or (II) described below:

(I) A method of performing an addition reaction on a hydrosilane compound having the specific silyl group expressed by Expression (3) (hereinafter, simply referred to as “hydrosilane compound (I)”) to a carbon-carbon double bond in a vinyl-based polymer having the carbon-carbon double bond (hereinafter, referred to as an “unsaturated vinyl-based polymer”) and

(II) A method of copolymerizing a silane compound expressed by Expression (4) (hereinafter, referred to as an “unsaturated silane compound (II)”) and a vinyl-based monomer.

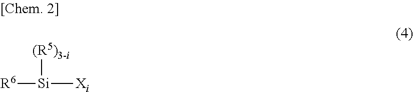

(in the expression, X, R⁵, and i represent respectively the same as X, R⁵, and i in Expression (3) above, and R⁶ represents an organic group having a polymerizable double bond.)

Examples of the hydrosilane compound (I) used in the method (I) include halogenized silanes such as methyldichlorosilane, trichlorosilane, and phenyldichlorosilane; alkoxysilanes such as methyldimethoxysilane, methyldiethoxysilane, phenyldimethoxysilane, trimethoxysilane, and triethoxysilane; acyloxysilanes such as methyldiacetoxysilane, phenyldiacetoxysilane, and triacetoxysilane; and aminoxysilanes such as methyldiaminoxysilane, triaminoxysilane, and dimethyl.aminoxysilane. These hydrosilane compounds (I) may be used singly, or two or more types thereof may be used in mixture.

In addition, the unsaturated vinyl-based polymer used in the method (I) is not particularly limited, as long as it is a polymer other than a polymer having a hydroxyl group. For example, the unsaturated vinyl-based polymer used in the method (I) can be manufactured by a method (I-1) or (I-2), or a combination thereof:

(I-1) A method of manufacturing an unsaturated vinyl-based polymer having a carbon-carbon double bond at a side chain of a polymer molecular chain (co)polymerizing a vinyl-based monomer having a functional group (hereinafter, referred to as “functional group (α)”) and reacting an unsaturated compound having a functional group (hereinafter, referred to as a “functional group (β)”) that can react with the functional group (α) and a carbon-carbon double bond with the functional group (α) in the (co)polymer.

(I-2) A method of manufacturing an unsaturated vinyl-based polymer having carbon-carbon double bonds at one or both terminals of a polymer molecular chain by using a radical polymerization initiator having the functional group (α) (for example, 4,4′-azobis-4-cyano valeric acid) or using a compound having the functional group (α) on both sides of a radical polymerization initiator and a chain transfer agent (for example, 4,4′-azobis-4-cyano valeric acid and dithio glycolic acid), (co)polymerizing a vinyl-based monomer, synthesizing a (co)polymer having the functional group (α) derived from the radical polymerization initiator or the chain transfer agent with one or both terminals of the polymer molecular chain, and reacting an unsaturated compound having the functional group (β) and the carbon-carbon double bond with the functional group (α) in the (co)polymer.

Examples of the reaction between the functional group (α) and the functional group (β) in the methods (I-1) and (I-2) include an etherification reaction between a carboxyl group and a hydroxyl group, a ring opening etherification reaction between a carboxylic anhydride group and a hydroxyl group, a ring opening etherification reaction between a carboxyl group and an epoxy group, an amidation reaction between a carboxyl group and an amino group, a ring opening amidation reaction between a carboxylic anhydride group and an amino group, a ring opening addition reaction between an epoxy group and an amino group, a urethanization reaction between a hydroxyl group and an isocyanate group, and a combination of the reactions.

### (Vinyl-Based Monomer)

### (i) Vinyl-Based Monomer Having Functional Group (α)

Examples of the vinyl-based monomer having the functional group (α) include an unsaturated carboxylic acid such as (meth)acrylic acid, crotonic acid, maleic acid, fumaric acid, and itaconic acid;

an unsaturated carboxylic anhydride such as maleic anhydride and itaconic anhydride;

a hydroxyl group-containing vinyl-based monomer such as 2-hydroxyethyl (meth)acrylate, 2-hydroxypropyl (meth)acrylate, 3-hydroxypropyl (meth)acrylate, N-methylol (meth)acrylamide, and 2-hydroxyethyl vinyl ether;

an amino group-containing vinyl-based monomer such as 2-aminoethyl (meth)acrylate, 2-aminopropyl (meth)acrylate, 3-aminopropyl (meth)acrylate, and 2-aminoethyl vinyl ether;

an amineimide group-containing vinyl-based monomer such as 1,1,1-trimethylamine (meth)acrylimide, 1-methyl-1-ethylamine (meth)acrylimide, 1,1-dimethyl-1-(2-hydroxypropyl)amine (meth)acrylimide, 1,1-dimethyl-1-(2′-phenyl-2′-hydroxyethyl)amine (meth)acrylimide, and 1,1-dimethyl-1-(2′-hydroxy-2′-phenoxypropyl)amine (meth)acrylimide; and

an epoxy group-containing vinyl-based monomer such as glycidyl (meth)acrylate and allyl glycidyl ether. The vinyl-based monomer having the functional groups (α) may be used singly, or two or more types thereof may be used in mixture.

### (ii) Other Vinyl-Based Monomer

Examples of other vinyl-based monomers that can be copolymerized with the vinyl-based monomer having the functional group (a) include an aromatic vinyl monomer such as styrene, α-methylstyrene, 4-methylstyrene, 2-methylstyrene, 3-methylstyrene, 4-methoxystyrene, 2-hydroxymethylstyrene, 4-ethylstyrene, 4-ethoxystyrene, 3,4-dimethylstyrene, 3,4-diethylstyrene, 2-chlorostyrene, 3-chlorostyrene, 4-chloro-3-methylstyrene, 4-t-butylstyrene, 2,4-dichlorostyrene, 2,6-dichlorostyrene, and 1-vinylnaphthalene;

an alkyl (meth)acrylate compound such as methyl (meth)acrylate, ethyl (meth)acrylate, propyl (meth)acrylate, n-butyl (meth)acrylate, i-butyl (meth)acrylate, amyl (meth)acrylate, i-amyl (meth)acrylate, hexyl (meth)acrylate, 2-ethylhexyl (meth)acrylate, n-octyl (meth)acrylate, and cyclohexyl (meth)acrylate;

a polyfunctional monomer such as divinylbenzene, ethylene glycol di(meth)acrylate, diethylene glycol di(meth)acrylate, triethylene glycol di(meth)acrylate, tetraethylene glycol di(meth)acrylate, propylene glycol di(meth)acrylate, dipropylene glycol di(meth)acrylate, tripropylene glycol di(meth)acrylate, tetrapropylene glycol di(meth)acrylate, butanediol di(meth)acrylate, hexanediol di(meth)acrylate, trimethylolpropane tri(meth)acrylate, and pentaerythritol tetra(meth)acrylate;

an acid amide compound such as (meth)acrylamide, N-methylol (meth)acrylamide, N-methoxymethyl (meth)acrylamide, N-butoxymethyl (meth)acrylamide, N,N′-methylenebisacrylamide, diacetone acrylamide, maleic acid amide, and maleimide;

a vinyl compound such as vinyl chloride, vinylidene chloride, and a fatty acid vinyl ester;

an aliphatic conjugated diene such as substituted straight chain conjugated pentadienes substituted with a substituted group such as 1,3-butandiene, 2-methyl-1,3-butandiene, 2,3-dimethyl-1,3-butandiene, 2-neopentyl-1,3-butandiene, 2-chloro-1,3-butandiene, 2-cyano-1,3-butandiene, isoprene, an alkyl group, a halogen atom, and a cyano group, and a straight chain-shaped and a side chain-shaped conjugated hexadiene;

a vinyl cyanide compound such as acrylonitrile and methacrylonitrile;

a fluorine atom-containing monomer such as trifluoroethyl (meth)acrylate, and pentadecafluorooctyl (meth)acrylate;

a piperidine-based monomer such as 4-(meth)acryloyloxy-2,2,6,6-tetramethylpiperidine, 4-(meth)acryloylamino-2,2,6,6-tetramethylpiperidine, and 4-(meth)acryloyloxy-1,2,2,6,6-pentamethylpiperidine;

an ultraviolet light-absorbing monomer such as 2-(2′-hydroxy-5′-methacryloxyethyl phenyl)-2H-benzotriazole, 2-(2′-hydroxy-3′-t-butyl-5′-methacryloxyethyl phenyl)-2H-benzotriazole, 2-hydroxy-4-(methacryloyloxy ethoxy)benzophenone, and 2-hydroxy-4-(acryloyloxy ethoxy)benzophenone; and

dicaprolactone. The vinyl-based monomers may be used singly, or two or more types thereof may be used in combination.

Examples of the unsaturated compound having the functional group (β) and the carbon-carbon double bond include a vinyl-based monomer which is the same as the vinyl-based monomer having the functional group (α) or an isocyanate group-containing unsaturated compound that causes a hydroxyl group-containing vinyl-based monomer and a diisocyanate compound to react with each other in an equimolar amount.

### (Unsaturated Silane Compound)

In addition, examples of the unsaturated silane compound (II) used in the method (II) include

CH₂═CHSi(CH₃)(OCH₃)₂, CH₂═CHSi(OCH₃)₃,

CH₂═CHSi(CH₃)Cl₂, CH₂═CHSiCl₃,

CH₂═CHCOO(CH₂)₂Si(CH₃)(OCH₃)₂,

CH₂═CHCOO(CH₂)₂Si(OCH₃)₃,

CH₂═CHCOO(CH₂)₃Si(CH₃)(OCH₃)₂,

CH₂═CHCOO(CH₂)₃Si(OCH₃)₃,

CH₂═CHCOO(CH₂)₂Si(CH₃)Cl₂,

CH₂═CHCOO(CH₂)₂SiCl₃,

CH₂═CHCOO(CH₂)₃Si(CH₃)Cl₂,

CH₂═CHCOO(CH₂)₃SiCl₃,

CH₂═C(CH₃)COO(CH₂)₂Si(CH₃)(OCH₃)₂,

CH₂═C(CH₃)COO(CH₂)₂Si(OCH₃)₃,

CH₂═C(CH₃)COO(CH₂)₃Si(CH₃)(OCH₃)₂,

CH₂═C(CH₃)COO(CH₂)₃Si(OCH₃)₃,

CH₂═C(CH₃)COO(CH₂)₂Si(CH₃)Cl₂,

CH₂═C(CH₃)COO(CH₂)₂SiCl₃,

CH₂═C(CH₃)COO(CH₂)₃Si(CH₃)Cl₂,

CH₂═C(CH₃)COO(CH₂)₃SiCl₃, and

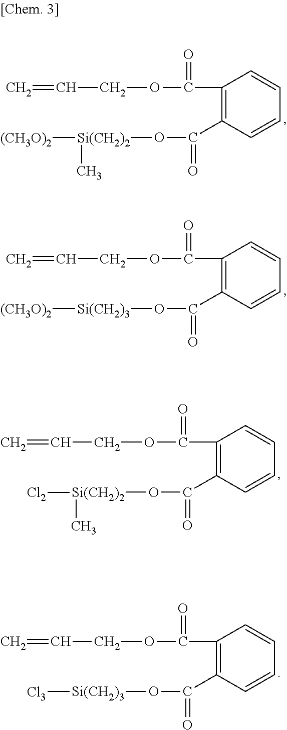

The unsaturated silane compounds (II) may be used singly or two or more types thereof may be used in combination.

In addition, examples of the other vinyl-based monomer that is copolymerized with the unsaturated silane compound include the vinyl-based monomer having the functional group (a) and the other vinyl-based monomer which are described in the method (I-1).

(Method of Manufacturing Specific Silyl Group-Containing Vinyl-Based Polymer (a2))

Examples of the method of manufacturing the specific silyl group-containing vinyl-based polymer (a2) include a method of collectively adding and polymerizing respective monomers, a method of polymerizing a portion of monomers and continuously or intermittently adding and polymerizing those remaining, and a method of continuously adding monomers from the start of polymerization. In addition, the polymerization methods may be combined.

A preferable polymerization method includes liquid polymerization. A solvent used in the liquid polymerization is not particularly limited, as long as the solvent can manufacture the specific silyl group-containing vinyl-based polymer (a2). Examples thereof include alcohols, aromatic carbonated hydrogens, ethers, ketones, and esters. Examples of the alcohols include methanol, ethanol, n-propyl alcohol, i-propyl alcohol, n-butyl alcohol, sec-butyl alcohol, t-butyl alcohol, isobutyl alcohol, n-hexyl alcohol, n-octyl alcohol, ethylene glycol, diethylene glycol, triethylene glycol, ethylene glycol monobutyl ether, ethylene glycol monoethyl ether acetate, diethylene glycol monoethyl ether, propylene glycol monomethyl ether, propylene monomethyl ether acetate, and diacetone alcohol.

In addition, examples of the aromatic carbonated hydrogens include benzene, toluene, and xylene, examples of ethers include tetrahydrofuran and dioxane, examples of ketones include acetone, methyl ethyl ketone, methyl isobutyl ketone, and diisobutyl ketone, and examples of esters include ethyl acetate, propyl acetate, butyl acetate, carbonated propylene, methyl lactate, ethyl lactate, n-propyl lactate, isopropyl lactate, methyl 3-ethoxypropionate, and ethyl 3-ethoxypropionate. The organic solvents may be used singly, or two or more types thereof may be used in mixture.

In addition, in the polymerization, as a polymerization initiator, a molecular weight regulator, a chelating agent, and an inorganic electrolyte, well-known products may be used.

In the embodiment, as the specific silyl group-containing vinyl-based polymer (a2), in addition to the specific silyl group-containing vinyl-based polymers which are polymerized in the method described above, the other specific silyl group-containing vinyl-based polymer such as a specific silyl group-containing epoxy resin and a specific silyl group-containing polyester resin can be used. The specific silyl group-containing epoxy resin can be manufactured by reacting, for example, amino silanes, vinyl silanes, carboxy silanes, or glycidyl silanes which have a specific silyl group with an epoxy group in the epoxy resin such as a bisphenol A-type epoxy resin, a bisphenol F-type epoxy resin, a hydrogenated bisphenol A-type epoxy resin, an aliphatic polyglycidyl ether, and an aliphatic polyglycidyl ester. In addition, the specific silyl group-containing polyester resin can be manufactured by reacting, for example, amino silanes, carboxy silanes, or glycidyl silanes, which have a specific silyl group with the carboxyl group or the hydroxyl group contained in the polyester resin.

The Mw of the specific silyl group-containing vinyl-based polymer (a2) in terms of polystyrene which is measured by the GPC method is preferably in the range of 2,000 to 100,000, and more preferably in the range of 3,000 to 50,000.

In the embodiment, the specific silyl group-containing vinyl-based polymers (a2) may be used singly, or two or more types thereof may be used in mixture.

### (Method of Preparing Polymer (A1))

The polymer (A1) according to the embodiment can be prepared by co-condensing the silane compound (a1) and the specific silyl group-containing vinyl-based polymer (a2). More particularly, the polymer (A1) can be prepared by adding and co-condensing a catalyst for the hydrolyzation and condensation reaction and water to the mixture of the silane compound (a1) and the specific silyl group-containing vinyl-based polymer (a2).

At this point, the weight ratio (Wa1/Wa2) between the content (Wa1) of the silane compound (a1) and the content (Wa2) of the specific silyl group-containing vinyl-based polymer (a2) is in the range of 5/95 to 95/5 and preferably in the range of 15/85 to 85/15 when Wa1+Wa2=100. In addition, Wa1 is a value of the silane compound (a1) in terms of completely hydrolyzed and condensed product, and Wa2 is a value of the specific silyl group-containing vinyl-based polymer (a2) in terms of the solid content. If the weight ratio (Wa1/Wa2) is in the range described above, a cured body having excellent transparency or excellent weather resistance can be obtained.

The polymer (A1) is preferably prepared particularly by methods (1) to (3) described below.

(1) The polymer (A1) is manufactured by adding an amount of water in the range described above to the mixture liquid of the silane compound (a1), the specific silyl group-containing vinyl-based polymer (a2), and the catalyst for the hydrolyzation and condensation reaction, by co-condensing the silane compound (a1) and the specific silyl group-containing vinyl-based polymer (a2) at the temperature in the range of 40° C. to 80° C., and for the reaction time in the range of 0.5 hours to 12 hours. Thereafter, other additives such as a stabilization improving agent may be added, if necessary.

(2) An amount of water in the range described above is added to the silane compound (a1), and the hydrolyzation and condensation reaction of the silane compound (a1) is performed at the temperature in the range of 40° C. to 80° C., and for the reaction time in the range of 0.5 hours to 12 hours. Subsequently, the specific silyl group-containing vinyl-based polymer (a2) and the catalyst for the hydrolyzation and condensation reaction are added and mixed, and further condensed and reacted at the temperature in the range of 40° C. to 80° C., and for the reaction time in the range of 0.5 hours to 12 hours, to prepare the polymer (A1). Thereafter, other additives such as a stabilization improving agent may be added, if necessary.

If an organic metal compound is used as the hydrolyzing and condensing catalyst, the stabilization improving agent is preferably added after the reaction.

The weight average molecular weight of the polymer (A1) obtained by the methods described above as a value in terms of polystyrene which is measured by the gel permeation chromatography is generally in the range of 3,000 to 200,000, preferably in the range of 4,000 to 150,000, and more preferably in the range of 5,000 to 100,000.

### (Catalyst)

In the embodiment, when the polymer (A1) is adjusted, in order to accelerate the hydrolyzation and condensation reaction between the silane compound (a1) and the specific silyl group-containing vinyl-based polymer (a2), a catalyst is preferably added to the mixture of the silane compound (a1) and the specific silyl group-containing vinyl-based polymer (a2). The degree of crosslinking of the obtained polymer (A1) can be increased by adding the catalyst, the molecular weight of the polysiloxane generated by the polycondensation reaction of the organosilane (1) increases, and as a result, a cured body having excellent strength, long term durability, or the like can be obtained. Further, the addition of the catalyst accelerates the reaction between the silane compound (a1) and the specific silyl group-containing vinyl-based polymer (a2), and forms a reaction site (alkoxy group) sufficient for the polymer (A1).

Examples of the catalyst used for accelerating this hydrolyzation and condensation reaction include a basic compound, an acidic compound, a salt compound, and an organic metal compound.

### (Basic Compound)

Examples of the basic compound include ammonia (including ammonia aqueous solution), an organic amine compound, a hydroxide of an alkali metal or an alkali earth metal such as sodium hydroxide and potassium hydroxide, and an alkoxide of an alkali metal such as sodium methoxide and sodium ethoxide. Among them, ammonia and the organic amine compound are preferable.

Examples of the organic amine include an alkylamine, an alkoxyamine, an alkanolamine, and an arylamine.

Examples of the alkylamine include an alkylamine having a 1-4C alkyl group such as methylamine, ethylamine, propylamine, butylamine, hexylamine, octylamine, N,N-dimethylamine, N,N-diethylamine, N,N-dipropylamine, N,N-dibutylamine, trimethylamine, triethylamine, tripropylamine, and tributylamine.

Examples of the alkoxyamine include an alkoxyamine having a 1-4C alkoxy group such as methoxymethylamine, methoxyethylamine, methoxypropylamine, methoxybutylamine, ethoxymethylamine, ethoxyethylamine, ethoxypropylamine, ethoxybutylamine, propoxymethylamine, propoxyethylamine, propoxypropylamine, propoxybutylamine, butoxymethylamine, butoxyethylamine, butoxypropylamine, and butoxybutylamine.

Examples of the alkanolamine include an alkanolamine having a 1-4C alkyl group such as methanolamine, ethanolamine, propanolamine, butanolamine, N-methylmethanolamine, N-ethylmethanolamine, N-ethylethanolamine, N-propylethanolamine, N-butylethanolamine, N-methylpropanolamine, N-ethylpropanolamine, N-propylpropanolamine, N-butylpropanolamine, N-methylbutanolamine, N-ethylbutanolamine, N-propylbutanolamine, N-butylbutanolamine, N,N-dimethylmethanolamine, N,N-diethylmethanolamine, N,N-dipropylmethanolamine, N,N-dibutylmethanolamine, N,N-dimethylethanolamine, N,N-diethylethanolamine, N,N-dipropylethanolamine, N,N-dibutylethanolamine, N,N-dimethylpropanolamine, N,N-diethylpropanolamine, N,N-dipropylpropanolamine, N,N-dibutylpropanolamine, N,N-dimethylbutanolamine, N,N-diethylbutanolamine, N,N-dipropylbutanolamine, N,N-dibutylbutanolamine, N-methyldimethanolamine, N-ethyldimethanolamine, N-propyldimethanolamine, N-butyldimethanolamine, N-methyldiethanolamine, N-ethyldiethanolamine, N-propyldiethanolamine, N-butyldiethanolamine, N-methyldipropanolamine, N-ethyldipropanolamine, N-propyldipropanolamine, N-butyldipropanolamine, N-methyldibutanolamine, N-ethyldibutanolamine, N-propyldibutanolamine, N-butyldibutanolamine, N-(aminomethyl)methanolamine, N-(aminomethyl)ethanolamine, N-(aminomethyl)propanolamine, N-(aminomethyl)butanolamine, N-(aminoethyl)methanolamine, N-(aminoethyl) ethanolamine, N-(aminoethyl)propanolamine, N-(aminoethyl)butanolamine, N-(aminopropyl)methanolamine, N-(aminopropyl) ethanolamine, N-(aminopropyl)propanolamine, N-(aminopropyl)butanolamine, N-(aminobutyl)methanolamine, N-(aminobutyl) ethanolamine, N-(aminobutyl)propanolamine, and N-(aminobutyl)butanolamine.

Examples of the arylamine include aniline and N-methylaniline.

Further, examples of an organic amine other than the above include a tetraalkylammonium hydroxide such as tetramethylammonium hydroxide, tetraethylammonium hydroxide, tetrapropylammonium hydroxide, and tetrabutylammonium hydroxide; a tetraalkyl ethylenediamine such as tetramethyl ethylenediamine, tetraethyl ethylenediamine, tetrapropyl ethylenediamine, and tetrabutyl ethylenediamine; an alkylaminoalkylamine such as methylaminomethylamine, methylaminoethylamine, methylaminopropylamine, methylaminobutylamine, ethylaminomethylamine, ethylaminoethylamine, ethylaminopropylamine, ethylaminobutylamine, propylaminomethylamine, propylaminoethylamine, propylaminopropylamine, propylaminobutylamine, butylaminomethylamine, butylaminoethylamine, butylaminopropylamine, and butylaminobutylamine; a polyamine such as ethylenediamine, hexamethylenediamine, diethylenetriamine, triethylenetetramine, tetraethylenepentamine, m-phenylenediamine, and p-phenylenediamine; pyridine, pyrrole, piperazine, pyrrolidine, piperidine, picoline, morpholine, methylmorpholine, diazabicyclooctane, diazabicyclononane, and diazabicycloundecene.

The basic compounds may be used singly, or two or more types thereof may be used in mixture. Among them, triethylamine, tetramethylammonium hydroxide, and pyridine are particularly preferable.

### (Acidic Compound)

As the acidic compound, organic acid and inorganic acid are included. Examples of the organic acid include acetic acid, propionic acid, butanoic acid, pentanoic acid, hexanoic acid, heptanoic acid, octanoic acid, nonanoic acid, decanoic acid, oxalic acid, maleic acid, maleic anhydride, methylmalonic acid, adipic acid, sebacic acid, gallic acid, butyric acid, mellitic acid, arachidonic acid, skimic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, methanesulfonic acid, phthalic acid, fumaric acid, citric acid, and tartaric acid. Examples of the inorganic acid include hydrochloric acid, nitric acid, sulfuric acid, hydrofluoric acid, and phosphoric acid.

The acidic compounds may be used singly, or two or more types thereof may be used in mixture. Among them, maleic acid, maleic anhydride, methanesulfonic acid, and acetic acid are particularly preferable.

### (Salt Compound)

Examples of the salt compound include alkali metal salts of naphthenic acid, octylic acid, nitrous acid, sulfurous acid, aluminic acid, and carbonic acid.

### (Organic Metal Compound)

The organic metal compound includes an organic metal compound and/or a partial hydrolysate thereof (hereinafter, an organic metal compound and/or a partial hydrolysate thereof are collectively referred to as “organic metal compounds”).

Examples of the organic metal compounds include a compound (hereinafter, referred to as “organic metal compound (a)”) expressed by Expression (a) below,

M¹(OR⁷)ᵣ(R⁸COCHCOR⁹)ₛ (a)

(in the expression, M¹ represents at least one metal atom selected from the group consisting of zirconium, titanium, and aluminum, R⁷ and R⁸ each independently represent a 1-6C univalent hydrocarbon group such as a methyl group, an ethyl group, an n-propyl group, an i-propyl group, an n-butyl group, a sec-butyl group, a t-butyl group, an n-pentyl group, an n-hexyl group, a cyclohexyl group, and a phenyl group, R⁹ represents the 1-6C univalent hydrocarbon group, or a 1-16C alkoxy group such as a methoxy group, an ethoxy group, an n-propoxy group, an i-propoxy group, an n-butoxy group, a sec-butoxy group, a t-butoxy group, a lauryloxy group, and a stearyloxy group, r and s each independently represent an integer of 0 to 4, and a relationship of (r+s)=(atom value of M¹) is satisfied.),

a tetravalent tin organic metal compound (hereinafter, referred to as “organic tin compound”) in which one or two 1-10C alkyl groups are bonded to one tin atom, or a partial hydrolysate thereof.

In addition, examples of the organic metal compounds include titanium alcoholates including tetraalkoxy titaniums such as tetramethoxy titanium, tetraethoxy titanium, tetra-i-propoxy titanium, and tetra-n-butoxy titanium; trialkoxy titaniums such as methyltrimethoxy titanium, ethyltriethoxy titanium, n-propyltrimethoxy titanium, i-propyltriethoxy titanium, n-hexyltrimethoxy titanium, cyclohexyltriethoxy titanium, phenyltrimethoxy titanium, 3-chloropropyltriethoxy titanium, 3-aminopropyltrimethoxy titanium, 3-aminopropyltriethoxy titanium, 3-(2-aminoethyl)-aminopropyltrimethoxy titanium, 3-(2-aminoethyl)-aminopropyltriethoxy titanium, 3-(2-aminoethyl)-aminopropylmethyldimethoxy titanium, 3-anilinopropyltrimethoxy titanium, 3-mercaptopropyltriethoxy titanium, 3-isocyanatepropyltrimethoxy titanium, 3-glycidoxypropyltriethoxy titanium, and 3-ureidopropyltrimethoxy titanium; and dialkoxy titaniums such as dimethyldiethoxy titanium, diethyldiethoxy titanium, di-n-propyldimethoxy titanium, di-i-propyldiethoxy titanium, di-n-pentyldimethoxy titanium, di-n-octyldiethoxy titanium, di-n-cyclohexyldimethoxy titanium, and diphenyldimethoxy titanium, and condensates thereof.

Examples of the organic metal compound (a) include an organic zirconium compound such as tetra-n-butoxy zirconium, tri-n-butoxy.ethyl acetoacetate zirconium, di-n-butoxy.bis (ethyl acetoacetate) zirconium, n-butoxy.tris(ethyl acetoacetate) zirconium, tetrakis(n-propyl acetoacetate) zirconium, tetrakis(acetyl acetoacetate)zirconium, tetrakis(ethyl acetoacetate)zirconium, and di-n-butoxy.bis (acetylacetonate) zirconium;

an organic titanium compound such as tetra-i-propoxy titanium, di-i-propoxy.bis (ethyl acetoacetate) titanium, di-i-propoxy.bis (acetylacetate) titanium, and di-i-propoxy.bis (acetylacetone) titanium;

an organic aluminum compound such as tri-i-propoxy aluminum, di-i-propoxy.ethyl acetoacetate aluminum, di-i-propoxy.acetylacetonate aluminum, i-propoxy.bis(ethyl acetoacetate)aluminum, i-propoxy.bis(acetylacetonate)aluminum, tris(ethyl acetoacetate)aluminum, tris(acetylacetonate)aluminum, and monoacetylacetonate.bis(ethyl acetoacetate)aluminum.

Examples of the organic tin compound include a carboxylic acid-type organic tin compound such as

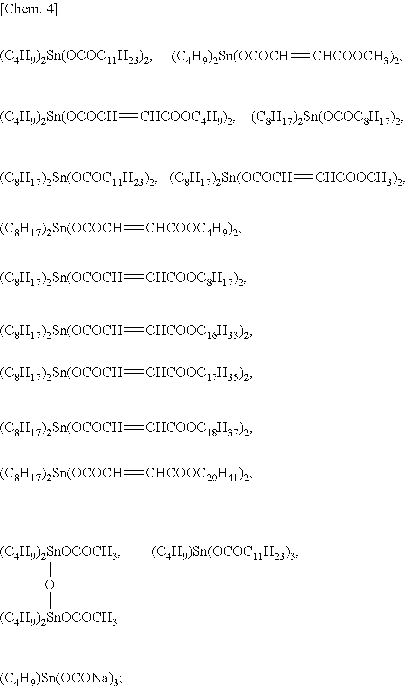

a mercaptide-type organic tin compound such as

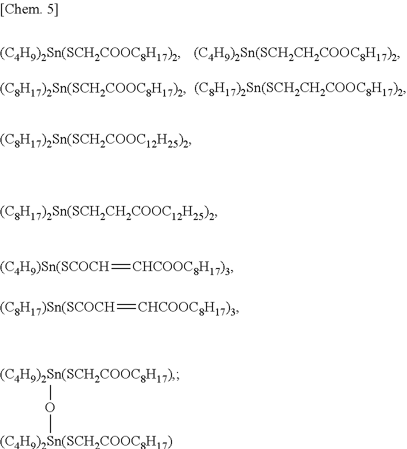

a sulfide-type organic tin compound such as

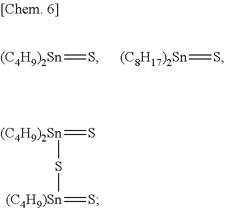

a chloride-type organic tin compound such as

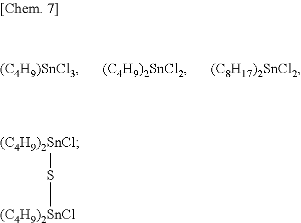

and

an organic tin oxide such as (C₄H₉)₂SnO, (C₈H₁₇)₂SnO, and reaction products of the organic tin oxide with a silicate and an ester compound such as dimethyl maleate, diethyl maleate, and dioctyl phthalate.

The organic metal compounds may be used singly, or two or more types thereof may be used in mixture. Among them, di-n-butoxy.bis (acetylacetonate) zirconium, dioctyltin.dioctyl maleate, di-i-propoxy.bis (acetylacetonate) titanium, di-i-propoxy.ethyl acetoacetate aluminum, and tris(ethyl acetoacetate)aluminum, or a partial hydrolysate thereof is preferable.

In addition, the catalyst may be used in mixture with a zinc compound or other reaction retardants.

If the catalyst is not the organic metal compounds, the used amount of the catalyst is generally in the range of 0.001 part by weight to 100 parts by weight, preferably in the range of 0.01 part by weight to 80 parts by weight, and more preferably in the range of 0.1 part by weight to 50 parts by weight with respect to 100 parts by weight of the silane compound (a1) (in terms of completely hydrolyzed and condensed product of the organosilane (1)). If the catalyst is the organic metal compounds, the used amount of the catalyst is generally 100 parts by weight or less, preferably in the range of 0.1 part by weight to 80 parts by weight, and more preferably in the range of 0.5 parts by weight to 50 parts by weight with respect to 100 parts by weight of the silane compound (a1) (in terms of completely hydrolyzed and condensed product of the organosilane (1)). If the used amount of the catalyst is greater than the upper limit, the preservation stability of the polymer (A1) is decreased to causing the polymer (A1) to be a gel, or the degree of crosslinking of the first layer extremely increases to generate cracks.

### (Stabilization Improving Agent)

According to the embodiment, in order to improve the preservation stability of the polymer (A1), it is preferable to add the stabilization improving agent after the polymer (A1) is prepared, if necessary. The stabilization improving agent used in the embodiment is at least one compound selected from the group consisting of β-diketones, β-ketoesters, a carboxylic acid compound, a dihydroxy compound, an amine compound and an oxyaldehyde compound expressed by Expression (b) below.

R¹⁰COCH₂COR¹¹ (b)

(in the expression, R¹⁰ represents a 1-6C univalent hydrocarbon group such as a methyl group, an ethyl group, an n-propyl group, an i-propyl group, an n-butyl group, a sec-butyl group, a t-butyl group, an n-pentyl group, an n-hexyl group, a cyclohexyl group, and a phenyl group, and R¹¹ represents the 1-6C univalent hydrocarbon group, or a 1-16C alkoxyl group such as a methoxy group, an ethoxy group, an n-propoxy group, an i-propoxy group, an n-butoxy group, a sec-butoxy group, a t-butoxy group, a lauryloxy group, and a stearyloxy group.)

When the organic metal compounds are used as the catalyst, the stabilization improving agent expressed by Expression (b) above is preferably added. If the stabilization improving agent is used, the stabilization improving agent is coordinated with a metal atom of the organic metal compounds, and thus it is considered that the coordination suppresses the excessive co-condensation reaction between the silane compound (a1) and the specific silyl group-containing vinyl-based polymer (a2), and further improves the preservation stability of the obtained polymer (A1).

Examples of the stabilization improving agents include acetylacetone, methyl acetoacetate, ethyl acetoacetate, n-propyl acetoacetate, i-propyl acetoacetate, n-butyl acetoacetate, sec-butyl acetoacetate, t-butyl acetoacetate, hexane-2,4-dione, heptane-2,4-dione, heptane-3,5-dione, octane-2,4-dione, nonane-2,4-dione, 5-methylhexane-2,4-dione, malonic acid, oxalic acid, phthalic acid, glycolic acid, salicylic acid, aminoacetic acid, iminoacetic acid, ethylenediaminetetraacetic acid, glycol, catechol, ethylenediamine, 2,2-bipyridine, 1,10-phenanthroline, diethylenetriamine, 2-ethanolamine, dimethylglyoxime, dithizone, methionine, and salicylaldehyde. Among them, acetylacetone and ethyl acetoacetate are preferable.

In addition, the stabilization improving agents may be used singly, or two or more types thereof may be used in mixture.

The amount of stabilization improving agent used in the embodiment is generally 2 mol or more, and preferably in the range of 3 mol to 20 mol with respect to 1 mol of the organic metal compound of the organic metal compounds. If the amount of the stabilization improving agent is less than the lower limit, the effect of improving the preservation stability of the obtained composition may be insufficient.

### (Water)

According to the embodiment, it is preferable that water is added to the mixture of the silane compound (a1) and the specific silyl group-containing vinyl-based polymer (a2), and the silane compound (a1) and the specific silyl group-containing vinyl-based polymer (a2) are co-condensed, to prepare the polymer (A1).

The added amount of water at this point is generally 0.1 mol to 1.0 mol, preferably in the range of 0.2 mol to 0.8 mol, and more preferably in the range of 0.25 mol to 0.6 mol with respect to 1 mol of all OR² groups in the silane compound (a1). If the added amount of water is in the range described above, the gelation hardly occurs, and the composition shows satisfactory preservation stability. In addition, the added amount of water is in the range described above, sufficiently crosslinked polymer (A1) can be obtained, and thus a composition including this polymer (A1) and the metal oxide particles (B) is used, to obtain the first layer.

### (Organic Solvent)

According to the embodiment, the hydrolyzation and condensation reaction between the silane compound (a1) and the specific silyl group-containing vinyl-based polymer (a2) may be performed in the organic solvent. At this point, the organic solvent used at the point of preparing the silyl group-containing vinyl-based polymer (a2) can be used as it is. In addition, in order to adjust a solid content concentration at the time of preparing the polymer (A1), an organic solvent can be added, if necessary. Further, the organic solvent used at the time of preparing the silyl group-containing vinyl-based polymer (a2) may be removed, and an organic solvent may be newly added.

The organic solvent in an amount preferably in the range of 10% by weight to 80% by weight, more preferably in the range of 15% by weight to 60% by weight, and particularly preferably in the range of 20% by weight to 50% by weight can be added in terms of the solid content concentration at the time of preparing the polymer (A1). In addition, if the organic solvent used at the time of preparing the silyl group-containing vinyl-based polymer (a2) is used as it is and the solid content concentration at the time of preparing the polymer (A1) is in the range described above, the organic solvent may be added or may not be added.

The reactivity between the silane compound (a1) and the specific silyl group-containing vinyl-based polymer (a2) can be controlled by adjusting the solid content concentration at the time of preparing the polymer (A1). If the solid content concentration at the time of preparing the polymer (A1) is less than the lower limit described above, the reactivity between the silane compound (a1) and the specific silyl group-containing vinyl-based polymer (a2) may be decreased. If the solid content concentration at the time of preparing the polymer (A1) is greater than the upper limit, the gelation may occur. In addition, the solid content amount in the solid content concentration is a total amount of the used amount (Wa1) of the silane compound (a1) in terms of the completely hydrolyzed and condensed product and the used amount (Wa2) of the specific silyl group-containing vinyl-based polymer (a2) in terms of the solid content.

The organic solvent is not particularly limited as long as the components are evenly mixed, and the examples thereof include alcohols, aromatic hydrocarbons, ethers, ketones, and esters, which are exemplified as the organic solvent used to manufacture the specific silyl group-containing vinyl-based polymer (a2). In addition, the organic solvents may be used singly, or two or more types thereof may be used in mixture.

### (Metal Oxide Particles (B))

The composition (I) according to the embodiment further contains the metal oxide particles (B).

The types of metal oxide particles are not particularly limited, as long as they are particles of oxides of metallic elements, and the examples thereof include antimony oxide, zirconium oxide, anatase-type titanium oxide, rutile-type titanium oxide, brookite-type titanium oxide, zinc oxide, tantalum oxide, indium oxide, hafnium oxide, tin oxide, niobium oxide, aluminum oxide, cerium oxide, scandium oxide, yttrium oxide, lanthanum oxide, praseodymium oxide, neodymium oxide, samarium oxide, europium oxide, gadolinium oxide, tervinium oxide, dysprosium oxide, holmium oxide, erbium oxide, thulium oxide, ytterbium oxide, lutetium oxide, calcium oxidre, gallium oxide, lithium oxide, strontium oxide, tungsten oxide, barium oxide, and magnesium oxide, and composites thereof, and oxides of composites of two or more kinds of metal such as an indium-tin composite oxide. In addition, as the metal oxide particles (B), particles of a composite oxide of silicon oxide and metal oxide or particles of an oxide in which the surface of the metal oxide is covered with silicon oxide may be used.

In the embodiment, the metal oxide particles (B) may be used singly, or two or more types thereof may be used in mixture. The metal oxide particles (B) can be appropriately selected according to the granted function, and, according to the embodiment, anatase-type titanium oxide, rutile-type titanium oxide, zirconium oxide, aluminum oxide, and zinc oxide are preferably used.

When the metal oxide particles (B) are combined, the metal oxide particles (B) may be used in the form of powder, or a solvent-based sol or colloid dispersed in a polar solvent such as isopropyl alcohol or in a nonpolar solvent such as toluene. The metal oxide particles (B) before addition may aggregate to form secondary particles. In addition, in order to improve the dispersibility of the metal oxide particles (B), a surface treatment may be performed to be used.

The primary particle size of the metal oxide particles (B) are generally in the range of 0.0001 μm to 1 μm, more preferably in the range of 0.001 μm to 0.5 μm, and particularly more preferably in the range of 0.002 μm to 0.2 μm. In the case of the metal oxide solvent-based sol or colloid, the solid content concentration is generally greater than 0% by weight and 50% by weight or less, and preferably in the range of 0.01% by weight to 40% by weight. If the metal oxide particles (B) are used in the form of a sol or colloid, the metal oxide particles (B) can be dispersed in the liquid by stirring blades or the like. Meanwhile, in the dispersion in the case where the metal oxide particles (B) are used as powder, a well-known disperser such as a ball mill, a sand mill (bead mill, high shear bead mill), a homogenizer, an ultrasonic homogenizer, a nanomizer, a propeller mixer, a high shear mixer, a paint shaker, a planetary mixer, a twin roll, a triple roll, and a kneader roll can be used, and particularly a highly dispersed fine particle dispersed body ball mill, a sand mill (bead mill, high shear bead mill), and a paint shaker are preferably used.

The used amount of the metal oxide particles (B) is generally 10% by weight or greater and 90% by weight or less, and preferably in the range of 20% by weight to 80% by weight in terms of the solid content with respect to the total solid content weight of the composition (I).

### (Curing Catalyst)

A curing catalyst can be further added to the composition (I) used in the embodiment. Examples of the curing catalyst include a basic compound, an acidic compound, a salt compound, and an organic metal compound which are used at the time of preparing the polymer (A1). The basic compounds may be used singly, or two or more types thereof may be used in mixture, and triethylamine, tetramethylammonium hydroxide, and pyridine are particularly preferable. The acidic compounds may be used singly, and two or more types thereof may be used in mixture, and maleic acid, maleic anhydride, methanesulfonic acid, and acetic acid are particularly preferable. The organic metal compounds may be used singly, or two or more types thereof may be used in mixture, and di-n-butoxy.bis(acetylacetonate)zirconium, dioctyltin.dioctyl maleate, di-i-propoxy.bis(acetylacetonate)titanium, di-i-propoxy.ethyl acetoacetate aluminum, and tris(ethyl acetoacetate)aluminum, and partial hydrolysates thereof are preferable.

### (Organic Solvent and Water)

An organic solvent or water may be further added to the composition (I) used in the embodiment to adjust the solid content concentration. As the organic solvent, products exemplified in the section of the preparation of the polymer (A1) can be used.

### (Arbitrary Addition Component)

A leveling agent, a wettability modifying agent, a surfactant, a plasticizer, an ultraviolet light absorber, an antioxidant, an antistatic agent, a silane coupling agent, and an inorganic filler other than the (B) components can be added to the composition (I) used in the embodiment, if necessary.

### (2-2) Method of Preparing the Composition (I)

The composition (I) used in the embodiment can be obtained by adding the metal oxide particles (B) to the silane compound (a1) and/or the polymer (A1) and performing the metal oxide dispersion process. In the dispersion process, (i) if a solvent-based sol or colloid is used as the metal oxide particles (B), a method of using a stirring blade or the like can be used, and (ii) if powder particles are used, a method of using a ball mill, a bead mill, a paint shaker, or the like can be used. The organic solvent, water, a stabilization improving agent, a curing catalyst, and an arbitrary addition component can be added to the composition (I), if necessary, and these may be added before the dispersion process, or may be added after the dispersion process.

In addition, with respect to the curing catalyst, since the metal oxide particles (B) work as a curing catalyst of the composition (I), the added amount of the curing catalyst may be decreased, if necessary.

(2-3) Method of Manufacturing Film with the Composition (I)

The composition (I) used in the embodiment is applied to a glass substrate, and is heated and dried to be cured.

The coating method is not particularly limited, and a method of using paint brush coating, brush coating, a bar coater, a knife coater, a doctor blade, screen printing, spray coating, a spin coater, an applicator, a roll coater, a flow coater, a centrifugal coater, an ultrasonic coater, a (micro)gravure coater, a dip coater, flexography, potting, and the like can be used, and the composition (I) may be used by being applied on other base materials (transferring base material) and be transferred.

The heating and drying is preferably performed by heating at a temperature in the range of 50° C. to 200° C. for a time in the range of 0.5 minutes to 180 minutes. For the heating and drying, a general oven is used, and a hot air-type oven, a convection-type oven, an infrared-type oven, and the like can be used. By the heating, the solvent is removed, the condensation reaction in the layer is progressed, and thus a stronger layer can be obtained.

The heating temperature is desirably high and the heating time is desirably long, because less of the solvent remains, and the condensation reaction is more progressed. In the heating process, the temperature may be increased in plural steps, or the heating may be performed by one step. According to the content, the boiling point, and the heating condition of the used solvent, the surface of an obtainable layer may be rough, and thus a proper heating process is desirably reviewed in advance.

### (3) Second Layer

The polyorganosiloxane (C) is contained in the second layer.

According to the use thereof, the second layer having a refractive index of 1.30 or greater and less than 1.50, and having a film thickness of 0.01 μm to 10 μm is used.

### (3-1) Composition (II)

The second layer is obtainable from a cured product of a composition containing at least one kind of silane compound (c1) selected from the group consisting of at least one kind of organosilane (hereinafter, referred to as “organosilane (2)”) expressed by Expression (2) below, a hydrolysate of the organosilane (2), and a condensate of the organosilane (2) (hereinafter, referred to as “composition (II)”).

R³ₘSi(OR⁴)₄₋ₘ (2)

(in the expression, R³ represents a 1-8C univalent organic group, and if there are two R³s, the R³s may be the same with or different from each other. R⁴ independently represents a 1-5C alkyl group or a 1-6C acyl group. m is an integer of 0 to 2.)

### (Silane Compound (C1))

The silane compound (c1) according to the embodiment is at least one kind of silane compound selected from the group consisting of the organosilane (2), a hydrolysate of the organosilane (2), and a condensate of the organosilane (2), and among the three kinds of silane compounds, only one kind of silane compound may be used, arbitrary two kinds of silane compounds may be used in mixture, or all three kinds of silane compounds may be used in mixture. In addition, if the organosilane (2) is used as the silane compound (c1), one kind of the organosilane (2) may be used singly, or two or more kinds thereof may be used in combination. In addition, the hydrolysate and the condensate of the organosilane (2) may be formed of one kind of organosilane (2), or may be formed of two or more kinds of organosilane (2) in combination.

The hydrolysate of the organosilane (2) may be obtained by hydrolyzing at least one of two to four OR⁴ groups contained in the organosilane (2). For example, the hydrolysate of the organosilane (2) may be one obtained by hydrolyzing one OR⁴ group, one obtained by hydrolyzing two or more OR⁴ groups, or the mixture thereof.

The condensate of the organosilane (2) is obtained by condensing a silanol group in the hydrolysate generated by hydrolyzing the organosilane (2) and thus forming the Si—O—Si bond. In the embodiment, all silanol groups do not have to be condensed, and the condensate may include one obtained by condensing a slight portion of the silanol group, one obtained by condensing most (including all) silanol groups, and further the mixture thereof.

In Expression (2), R³ represents a 1-8C univalent organic group, and specific examples thereof include an alkyl group such as a methyl group, an ethyl group, an n-propyl group, an i-propyl group, an n-butyl group, an i-butyl group, a sec-butyl group, a t-butyl group, an n-hexyl group, an n-heptyl group, an n-octyl group, and a 2-ethylhexyl group; an acyl group such as an acetyl group, a propionyl group, a butyryl group, a valeryl group, a benzoyl group, a trioyl group, and a caproyl group;

a vinyl group, an allyl group, a cyclohexyl group, a phenyl group, an epoxy group, a glycidyl group, a (meth)acryloxy group, a ureido group, an amide group, a fluoroacetamide group, and an isocyanate group.

Further, as R³, substituted derivatives of the organic groups may be included. Examples of the substituted group of the substituted derivative of R³ include a halogen atom, a substituted or non-substituted amino group, a hydroxyl group, a mercapto group, an isocyanate group, a glycidoxy group, a 3,4-epoxycyclohexyl group, a (meth)acryloxy group, a ureido group, and an ammonium salt group. However, the number of carbon atoms of R³ formed of these substituted derivatives is preferably eight or less including carbon atoms in a substituted group. If plural R³s exist in Expression (2), the R³s may be the same with or different from each other.

Examples of R⁴ which is a 1-5C alkyl group include a methyl group, an ethyl group, an n-propyl group, an i-propyl group, an n-butyl group, a sec-butyl group, a t-butyl group, and an n-pentyl group, and examples of R⁴ which is a 1-6C acyl group include an acetyl group, a propionyl group, a butyryl group, a valeryl group, and a caproyl group. If plural R⁴s exist in Expression (2), the R⁴s may be the same with or different from each other.

Specific examples of the organosilane (2) include tetraalkoxysilanes such as tetramethoxysilane, tetraethoxysilane, tetra-n-propoxysilane, tetra-i-propoxysilane, and tetra-n-butoxysilane (n=0 in Expression (2));

trialkoxysilanes such as methyltrimethoxysilane, methyltriethoxysilane, ethyltrimethoxysilane, ethyltriethoxysilane, n-propyltrimethoxysilane, n-propyltriethoxysilane, i-propyltrimethoxysilane, i-propyltriethoxysilane, n-butyltrimethoxysilane, n-butyltriethoxysilane, n-pentyltrimethoxysilane, n-hexyltrimethoxysilane, n-heptyltrimethoxysilane, n-octyltrimethoxysilane, vinyltrimethoxysilane, vinyltriethoxysilane, cyclohexyltrimethoxysilane, cyclohexyltriethoxysilane, phenyltrimethoxysilane, phenyltriethoxysilane, 3-chloropropyltrimethoxysilane, 3-chloropropyltriethoxysilane, 3,3,3-trifluoropropyltrimethoxysilane, 3,3,3-trifluoropropyltriethoxysilane, 3-aminopropyltrimethoxysilane, 3-aminopropyltriethoxysilane, 2-hydroxyethyltrimethoxysilane, 2-hydroxyethyltriethoxysilane, 2-hydroxypropyltrimethoxysilane, 2-hydroxypropyltriethoxysilane, 3-hydroxypropyltrimethoxysilane, 3-hydroxypropyltriethoxysilane, 3-mercaptopropyltrimethoxysilane, 3-mercaptopropyltriethoxysilane, 3-isocyanatopropyltrimethoxysilane, 3-isocyanatopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, 3-(meth)acryloxypropyltrimethoxysilane, 3-(meth)acryloxypropyltriethoxysilane, 3-ureidopropyltrimethoxysilane, and 3-ureidopropyltriethoxysilane (n=1 in Expression (2));

dialkoxysilanes such as dimethyldimethoxysilane, dimethyldiethoxysilane, diethyldimethoxysilane, diethyldiethoxysilane, di-n-propyldimethoxysilane, di-n-propyldiethoxysilane, di-i-propyldimethoxysilane, di-i-propyldiethoxysilane, di-n-butyldimethoxysilane, di-n-butyldiethoxysilane, di-n-pentyldimethoxysilane, di-n-pentyldiethoxysilane, di-n-hexyldimethoxysilane, di-n-hexyldiethoxysilane, di-n-heptyldimethoxysilane, di-n-heptyldiethoxysilane, di-n-octyldimethoxysilane, di-n-octyldiethoxysilane, di-n-cyclohexyldimethoxysilane, di-n-cyclohexyldiethoxysilane, diphenyldimethoxysilane, and diphenyldiethoxysilane (n=2 in Expression (2));

methyltriacetyloxysilane (n=1 in Expression (2)), and dimethyldiacetyloxysilane (n=2 in Expression (2)).

Among them, trifunctional organosilane (2) in which n=1 in Expression (2) is mainly used, and trialkoxysilanes are particularly preferable. Bifunctional organosilane (2) in which n=2 in Expression (2) is mainly used in combination.

If the trifunctional organosilane (2) and the bifunctional organosilane (2) are used in combination, the weight ratio of the trifunctional organosilane (2)/bifunctional organosilane (2) respectively in terms of completely hydrolyzed and condensed products is preferably in the range of 100/0 to 10/90, more preferably in the range of 100/0 to 30/70, and particularly preferably in the range of 100/0 to 40/60. However, the sum of the trifunctional organosilane (2) and the bifunctional organosilane (2) (in terms of completely hydrolyzed and condensed products) is 100. If the content of the trifunctional organosilane (2) is too much, the preservation stability of the composition (II) may be deteriorated. If the content of the trifunctional organosilane (2) is too small, curing properties of the cured body may be deteriorated. In addition, in the specification, the completely hydrolyzed and condensed product refers to a product in which 100% of an —OR group of the silane compound is hydrolyzed to become a SiOH group, and is completely condensed to become a siloxane structure.

In the embodiment, as the silane compound (c1), one type of organosilane (2) may be used singly, and two or more types of the organosilane (2) may be used in combination. If two or more types of organosilane (2) used as the silane compound (c1) are averaged and shown in Expression (2) above, the averaged n (hereinafter, referred to as an “average value of n”) is preferably in the range of 0.5 to 1.9, more preferably in the range of 0.6 to 1.8, and particularly preferably in the range of 0.7 to 1.7. If the average value of n is less than the lower limit, the preservation stability of the silane compound (c1) may be deteriorated. If the average value of n is greater than the upper limit, the curing properties of the cured body (coated film) may be deteriorated.

The average value of n can be adjusted to the range described above, by appropriately using bifunctional to tetrafunctional organosilane (2) in combination, and appropriately adjusting the combination ratio thereof.

In addition, this is the same when the hydrolysate or the condensate of the organosilane (2) is used as the silane compound (c1).

In the embodiment, as the silane compound (c1), the organosilane (2) may be used as it is, but the hydrolysate and/or the condensate of the organosilane (2) can be used in combination. If the hydrolysate and/or the condensate of the organosilane (2) is used, a product manufactured by hydrolyzing and condensing the organosilane (2) in advance may be used. However, as described below, when the composition (II) is prepared, the hydrolysate and/or the condensate of the organosilane (2) may be prepared by adding water and hydrolyzing and condensing the organosilane (2) and water.

The weight average molecular weight (hereinafter, presented as “Mw”) of the condensate of the organosilane (2) in terms of polystyrene, which is measured by a gel permeation chromatography method (GPC method) is preferably in the range of 300 to 100,000, and more preferably in the range of 500 to 50,000.

If the condensate of the organosilane (2) is used as the silane compound (c1) according to the embodiment, the condensate may be prepared with the organosilane (2), or the commercially available condensate of the organosilane may be used. Examples of the commercially available condensate of the organosilane include MKC silicate manufactured by Mitsubishi Chemical Corporation, ethyl silicate manufactured by Colcoat Co., Ltd., a silicone resin or a silicone oligomer manufactured by Dow Corning Toray Co., Ltd., a silicone resin or a silicone oligomer manufactured by Momentive Performance Materials Inc., a silicone resin or a silicone oligomer manufactured by Shin-Etsu Chemical Co., Ltd., and hydroxyl group-containing polydimethylsiloxane manufactured by Dow Corning Asia. The commercially available condensate of the organosilane may be used as it is, or may be further condensed to be used. If the second layer is formed by laminating and curing the composition (II) on the previously formed first layer, the second layer can function as a low refractive index layer and can be used as an antireflective laminated body.

### (Polymer C1)

In the embodiment, as the composition (II), the polymer (C1) prepared by performing a hydrolyzation and condensation reaction between the silane compound (c1) and a vinyl-based polymer (c2) containing a specific silyl group may be used. More specifically, the polymer (C1) is prepared by adding a catalyst that accelerates the hydrolyzation and condensation reaction and water to a mixture containing the silane compound (c1) and the vinyl-based polymer (c2) containing the silyl group.

### (Silyl Group-Containing Vinyl-Based Polymer (C2))

The vinyl-based polymer (c2) containing the specific silyl group used in the embodiment (hereinafter, referred to as “specific silyl group-containing vinyl-based polymer (c2)”) contains a silyl group having a silicon atom obtained by bonding the hydrolyzable group and/or the hydroxyl group (hereinafter, referred to as “specific silyl group”). The specific silyl group-containing vinyl-based polymer (c2) preferably has a specific silyl group at a terminal and/or a side chain of a polymer molecular chain.

The polymer (C1) is formed by co-condensing the hydrolyzable group and/or hydroxyl group in the specific silyl group with the silane compound (c1). If the composition containing the polymer (C1) is coated on the first layer, the first layer can function as a low refractive index layer and can be used as an antireflective laminated body.

The content of the specific silyl group in the specific silyl group-containing vinyl-based polymer (c2) in terms of the amount of the silicon atom is generally in the range of 0.1% by weight to 2% by weight, and preferably in the range of 0.3% by weight to 1.7% by weight with respect to the polymer before the specific silyl group is introduced. If the content of the specific silyl group in the specific silyl group-containing vinyl-based polymer (c2) is less than the lower limit, a bonding portion shared with the silane compound (c1) or a remaining specific silyl group becomes small so that the required strength of the coated layer may not be obtained. Meanwhile, if the content is greater than the upper limit, gelation may occur when the composition is preserved.

### (Specific Silyl Group)

The specific silyl group is preferably a group expressed by Expression (5) below.

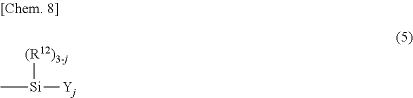

(in the expression, Y represents a hydrolyzable group such as a halogen atom, an alkoxyl group, an acetoxy group, a phenoxy group, a thioalkoxyl group, and an amino group, or a hydroxyl group, R¹² represents a hydrogen atom, a 1-10C alkyl group, or a 1-10C aralkyl group, and j represents an integer of 1 to 3.)

(Method of Manufacturing Specific Silyl Group-Containing Vinyl-Based Polymer (c2))

This specific silyl group-containing vinyl-based polymer (c2) can be manufactured, for example, by a method of (I′) or (II′) described below:

(I′) A method of performing an addition reaction on a hydrosilane compound having the specific silyl group expressed by Expression (5) (hereinafter, simply referred to as “hydrosilane compound (I′)”) to a carbon-carbon double bond in a vinyl-based polymer having the carbon-carbon double bond (hereinafter, referred to as an “unsaturated vinyl-based polymer”) and

(II′) A method of copolymerizing a silane compound expressed by Expression (6) (hereinafter, referred to as an “unsaturated silane compound (II′)”) and a vinyl-based monomer.

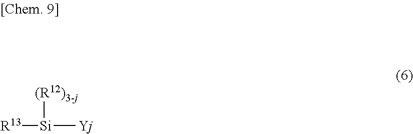

(in the expression, Y, R¹², and j represent respectively the same as Y, R¹², and j in Expression (5) above, and R¹³ represents an organic group having a polymerizable double bond.)

Examples of the hydrosilane compound (I′) used in the method (I′) include halogenized silanes such as methyldichlorosilane, trichlorosilane, and phenyldichlorosilane; alkoxysilanes such as methyldimethoxysilane, methyldiethoxysilane, phenyldimethoxysilane, trimethoxysilane, and triethoxysilane; acyloxysilanes such as methyldiacetoxysilane, phenyldiacetoxysilane, and triacetoxysilane; and aminoxysilanes such as methyldiaminoxysilane, triaminoxysilane, and dimethyl.aminoxysilane. These hydrosilane compounds (I′) may be used singly, or two or more types thereof may be used in mixture.

In addition, the unsaturated vinyl-based polymer used in the method (I′) is not particularly limited, as long as it is a polymer other than a polymer having a hydroxyl group. For example, the unsaturated vinyl-based polymer used in the method (I′) can be manufactured by a method (I′-1) or (I′-2), or a combination thereof.

(I′-1) A method of manufacturing an unsaturated vinyl-based polymer having a carbon-carbon double bond at a side chain of a polymer molecular chain (co)polymerizing a vinyl-based monomer having a functional group (hereinafter, referred to as “functional group (α′)”) and reacting an unsaturated compound having a functional group (hereinafter, referred to as a “functional group (β′)”) that can react with the functional group (α′) and a carbon-carbon double bond with the functional group (α′) in the (co)polymer.

(I′-2) A method of manufacturing an unsaturated vinyl-based polymer having carbon-carbon double bonds at one or both terminals of a polymer molecular chain by using a radical polymerization initiator having the functional group (α′) (for example, 4,4′-azobis-4-cyano valeric acid) or using a compound having the functional group (α′) on both sides of a radical polymerization initiator and a chain transfer agent (for example, 4,4′-azobis-4-cyano valeric acid and dithio glycolic acid), (co)polymerizing a vinyl-based monomer, synthesizing a (co)polymer having the functional group (α′) derived from the radical polymerization initiator or the chain transfer agent with one or both terminals of the polymer molecular chain, and reacting an unsaturated compound having the functional group (β′) and the carbon-carbon double bond with the functional group (α′) in the (co)polymer.

Examples of the reaction between the functional group (α′) and the functional group (β′) in the methods (I′-1) and (I′-2) include an etherification reaction between a carboxyl group and a hydroxyl group, a ring opening etherification reaction between a carboxylic anhydride group and a hydroxyl group, a ring opening etherification reaction between a carboxyl group and an epoxy group, an amidation reaction between a carboxyl group and an amino group, a ring opening amidation reaction between a carboxylic anhydride group and an amino group, a ring opening addition reaction between an epoxy group and an amino group, a urethanization reaction between a hydroxyl group and an isocyanate group, and a combination of the reactions.

### (Vinyl-Based Monomer)

(i′) Vinyl-Based Monomer Having Functional Group (α′)

Examples of the vinyl-based monomer having the functional group (α′) include an unsaturated carboxylic acid such as (meth)acrylic acid, crotonic acid, maleic acid, fumaric acid, and itaconic acid;

an unsaturated carboxylic anhydride such as maleic anhydride and itaconic anhydride;

a hydroxyl group-containing vinyl-based monomer such as 2-hydroxyethyl (meth)acrylate, 2-hydroxypropyl (meth)acrylate, 3-hydroxypropyl (meth)acrylate, N-methylol (meth)acrylamide, and 2-hydroxyethyl vinyl ether;

an amino group-containing vinyl-based monomer such as 2-aminoethyl (meth)acrylate, 2-aminopropyl (meth)acrylate, 3-aminopropyl (meth)acrylate, and 2-aminoethyl vinyl ether;

an amineimide group-containing vinyl-based monomer such as 1,1,1-trimethylamine (meth)acrylimide, 1-methyl-1-ethylamine (meth)acrylimide, 1,1-dimethyl-1-(2-hydroxypropyl)amine (meth)acrylimide, 1,1-dimethyl-1-(2′-phenyl-2′-hydroxyethyl)amine (meth)acrylimide, and 1,1-dimethyl-1-(2′-hydroxy-2′-phenoxypropyl)amine (meth)acrylimide; and

an epoxy group-containing vinyl-based monomer such as glycidyl (meth)acrylate and allyl glycidyl ether. The vinyl-based monomer having the functional groups (a′) may be used singly, or two or more types thereof may be used in mixture.

(ii′) Other Vinyl-Based Monomer

Examples of other vinyl-based monomers that can be copolymerized with the vinyl-based monomer having the functional group (α′) include an aromatic vinyl monomer such as styrene, α-methylstyrene, 4-methylstyrene, 2-methylstyrene, 3-methylstyrene, 4-methoxystyrene, 2-hydroxymethylstyrene, 4-ethylstyrene, 4-ethoxystyrene, 3,4-dimethylstyrene, 3,4-diethylstyrene, 2-chlorostyrene, 3-chlorostyrene, 4-chloro-3-methylstyrene, 4-t-butylstyrene, 2,4-dichlorostyrene, 2,6-dichlorostyrene, and 1-vinylnaphthalene;

an alkyl (meth)acrylate compound such as methyl (meth)acrylate, ethyl (meth)acrylate, propyl (meth)acrylate, n-butyl (meth)acrylate, i-butyl (meth)acrylate, amyl (meth)acrylate, i-amyl (meth)acrylate, hexyl (meth)acrylate, 2-ethylhexyl (meth)acrylate, n-octyl (meth)acrylate, and cyclohexyl (meth)acrylate;

a polyfunctional monomer such as divinylbenzene, ethylene glycol di(meth)acrylate, diethylene glycol di(meth)acrylate, triethylene glycol di(meth)acrylate, tetraethylene glycol di(meth)acrylate, propylene glycol di(meth)acrylate, dipropylene glycol di(meth)acrylate, tripropylene glycol di(meth)acrylate, tetrapropylene glycol di(meth)acrylate, butanediol di(meth)acrylate, hexanediol di(meth)acrylate, trimethylolpropane tri(meth)acrylate, and pentaerythritol tetra(meth)acrylate;

an acid amide compound such as (meth)acrylamide, N-methylol (meth)acrylamide, N-methoxymethyl (meth)acrylamide, N-butoxymethyl (meth)acrylamide, N,N′-methylenebisacrylamide, diacetone acrylamide, maleic acid amide, and maleimide;

a vinyl compound such as vinyl chloride, vinylidene chloride, and a fatty acid vinyl ester;

an aliphatic conjugated diene such as substituted straight chain conjugated pentadienes substituted with a substituted group such as 1,3-butandiene, 2-methyl-1,3-butandiene, 2,3-dimethyl-1,3-butandiene, 2-neopentyl-1,3-butandiene, 2-chloro-1,3-butandiene, 2-cyano-1,3-butandiene, isoprene, an alkyl group, a halogen atom, and a cyano group, and a straight chain-shaped and a side chain-shaped conjugated hexadiene;

a vinyl cyanide compound such as acrylonitrile and methacrylonitrile;

a fluorine atom-containing monomer such as trifluoroethyl (meth)acrylate, and pentadecafluorooctyl (meth)acrylate;

a piperidine-based monomer such as 4-(meth)acryloyloxy-2,2,6,6-tetramethylpiperidine, 4-(meth)acryloylamino-2,2,6,6-tetramethylpiperidine, and 4-(meth)acryloyloxy-1,2,2,6,6-pentamethylpiperidine;

an ultraviolet light-absorbing monomer such as 2-(2′-hydroxy-5′-methacryloxyethyl phenyl)-2H-benzotriazole, 2-(2′-hydroxy-3′-t-butyl-5′-methacryloxyethyl phenyl)-2H-benzotriazole, 2-hydroxy-4-(methacryloyloxy ethoxy)benzophenone, and 2-hydroxy-4-(acryloyloxy ethoxy)benzophenone; and

dicaprolactone. The vinyl-based monomers may be used singly, or two or more types thereof may be used in combination.

Examples of the unsaturated compound having the functional group (β′) and the carbon-carbon double bond include a vinyl-based monomer which is the same as the vinyl-based monomer having the functional group (α′) or an isocyanate group-containing unsaturated compound that causes a hydroxyl group-containing vinyl-based monomer and a diisocyanate compound to react with each other in an equimolar amount.

### (Unsaturated Silane Compound)

In addition, examples of the unsaturated silane compound (II′) used in the method (II′) include

CH₂═CHSi(CH₃)(OCH₃)₂, CH₂═CHSi(OCH₃)₃,

CH₂═CHSi(CH₃) Cl₂, CH₂═CHSiCl₃,

CH₂═CHCOO(CH₂)₂Si(CH₃)(OCH₃)₂,

CH₂═CHCOO(CH₂)₂Si(OCH₃)₃,

CH₂═CHCOO(CH₂)₃Si(CH₃)(OCH₃)₂,

CH₂═CHCOO(CH₂)₃Si(OCH₃)₃,

CH₂═CHCOO(CH₂)₂Si(CH₃)Cl₂,

CH₂═CHCOO(CH₂)₂SiCl₃,

CH₂═CHCOO(CH₂)₃Si(CH₃)Cl₂,

CH₂═CHCOO(CH₂)₃SiCl₃,

CH₂═C(CH₃)COO(CH₂)₂Si(CH₃)(OCH₃)₂,

CH₂═C(CH₃)COO(CH₂)₂Si(OCH₃)₃,

CH₂═C(CH₃)COO(CH₂)₃Si(CH₃)(OCH₃)₂,

CH₂═C(CH₃)COO(CH₂)₃Si(OCH₃)₃,

CH₂═C(CH₃)COO(CH₂)₂Si(CH₃)Cl₂,

CH₂═C(CH₃)COO(CH₂)₂SiCl₃,

CH₂═C(CH₃)COO(CH₂)₃Si(CH₃)Cl₂,

CH₂═C(CH₃)COO(CH₂)₃SiCl₃, and

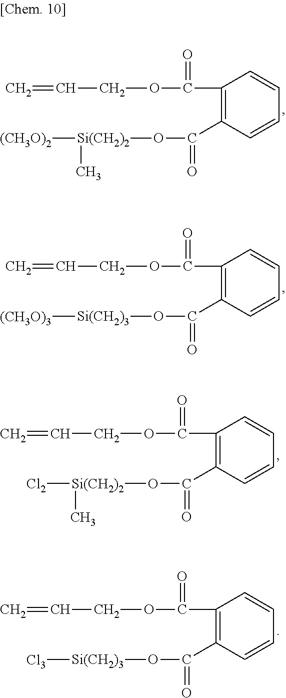

The unsaturated silane compounds (II′) may be used singly or two or more types thereof may be used in combination.

In addition, examples of the other vinyl-based monomer that is copolymerized with the unsaturated silane compound include the vinyl-based monomer having the functional group (α′) and the other vinyl-based monomer which are described in the method (I′-1).

(Method of Manufacturing Specific Silyl Group-Containing Vinyl-Based Polymer (c2))

Examples of the method of manufacturing the specific silyl group-containing vinyl-based polymer (c2) include a method of collectively adding and polymerizing respective monomers, a method of polymerizing a portion of monomers and continuously or intermittently adding and polymerizing those remaining, and a method of continuously adding monomers from the start of polymerization. In addition, the polymerization methods may be combined.

A preferable polymerization method includes liquid polymerization. A solvent used in the liquid polymerization is not particularly limited, as long as the solvent can manufacture the specific silyl group-containing vinyl-based polymer (c2). Examples thereof include alcohols, aromatic carbonated hydrogens, ethers, ketones, and esters. Examples of the alcohols include methanol, ethanol, n-propyl alcohol, i-propyl alcohol, n-butyl alcohol, sec-butyl alcohol, t-butyl alcohol, isobutyl alcohol, n-hexyl alcohol, n-octyl alcohol, ethylene glycol, diethylene glycol, triethylene glycol, ethylene glycol monobutyl ether, ethylene glycol monoethyl ether acetate, diethylene glycol monoethyl ether, propylene glycol monomethyl ether, propylene monomethyl ether acetate, and diacetone alcohol.

In addition, examples of the aromatic carbonated hydrogens include benzene, toluene, and xylene, examples of ethers include tetrahydrofuran and dioxane, examples of ketones include acetone, methyl ethyl ketone, methyl isobutyl ketone, and diisobutyl ketone, and examples of esters include ethyl acetate, propyl acetate, butyl acetate, carbonated propylene, methyl lactate, ethyl lactate, n-propyl lactate, isopropyl lactate, methyl 3-ethoxypropionate, and ethyl 3-ethoxypropionate. The organic solvents may be used singly, or two or more types thereof may be used in mixture.

In addition, in the polymerization, as a polymerization initiator, a molecular weight regulator, a chelating agent, and an inorganic electrolyte, well-known products may be used.

In the embodiment, as the specific silyl group-containing vinyl-based polymer (c2), in addition to the specific silyl group-containing vinyl-based polymers which are polymerized in the method described above, a specific silyl group-containing vinyl-based polymer such as a specific silyl group-containing epoxy resin and a specific silyl group-containing polyester resin can be used. The specific silyl group-containing epoxy resin can be manufactured by reacting, for example, amino silanes, vinyl silanes, carboxy silanes, or glycidyl silanes which have a specific silyl group with an epoxy group in the epoxy resin such as a bisphenol A-type epoxy resin, a bisphenol F-type epoxy resin, a hydrogenated bisphenol A-type epoxy resin, aliphatic polyglycidyl ether, and an aliphatic polyglycidyl ester. In addition, the specific silyl group-containing polyester resin can be manufactured by reacting, for example, amino silanes, carboxy silanes, or glycidyl silanes, which have a specific silyl group with the carboxyl group or the hydroxyl group contained in the polyester resin.

The Mw of the specific silyl group-containing vinyl-based polymer (c2) in terms of polystyrene which is measured by the GPC method is preferably in the range of 2,000 to 100,000, and more preferably in the range of 3,000 to 50,000.

In the embodiment, the specific silyl group-containing vinyl-based polymers (c2) may be used singly, or two or more types thereof may be used in mixture.

### (Method of Preparing Polymer (C1))

The polymer (C1) according to the embodiment can be prepared by co-condensing the silane compound (c1) and the specific silyl group-containing vinyl-based polymer (c2). More particularly, the polymer (C1) can be prepared by adding and co-condensing a catalyst for the hydrolyzation and condensation reaction and water to the mixture of the silane compound (c1) and the specific silyl group-containing vinyl-based polymer (c2).

At this point, the weight ratio (Wc1/Wc2) between the content (Wc1) of the silane compound (c1) and the content (Wc2) of the specific silyl group-containing vinyl-based polymer (c2) is in the range of 5/95 to 95/5 and preferably in the range of 15/85 to 85/15 when Wc1+Wc2=100. In addition, Wc1 is a value of the silane compound (c1) in terms of completely hydrolyzed and condensed product, and Wc2 is a value of the specific silyl group-containing vinyl-based polymer (c2) in terms of the solid content. If the weight ratio (Wc1/Wc2) is in the range described above, a cured body having excellent transparency or excellent weather resistance can be obtained.

The polymer (C1) is preferably prepared particularly by methods (1) to (3) described below.

(1) The polymer (C1) is manufactured by adding an amount of water in the range described above to the mixture liquid of the silane compound (c1), the specific silyl group-containing vinyl-based polymer (c2), and the catalyst for the hydrolyzation and condensation reaction, by co-condensing the silane compound (c1) and the specific silyl group-containing vinyl-based polymer (c2) at the temperature in the range of 40° C. to 80° C., and for the reaction time in the range of 0.5 hours to 12 hours. Thereafter, other additives such as a stabilization improving agent may be added, if necessary.

(2) An amount of water in the range described above is added to the silane compound (c1), and the hydrolyzation and condensation reaction of the silane compound (c1) is performed at the temperature in the range of 40° C. to 80° C., and for the reaction time in the range of 0.5 hours to 12 hours. Subsequently, the specific silyl group-containing vinyl-based polymer (c2) and the catalyst for the hydrolyzation and condensation reaction are added and mixed, and further condensed and reacted at the temperature in the range of 40° C. to 80° C., and for the reaction time in the range of 0.5 hours to 12 hours, to prepare the polymer (C1). Thereafter, other additives such as a stabilization improving agent may be added, if necessary.

If an organic metal compound is used as the hydrolyzing and condensing catalyst, the stabilization improving agent is preferably added after the reaction.

The weight average molecular weight of the polymer (C1) obtained by the methods described above as a value in terms of polystyrene which is measured by the gel permeation chromatography is generally in the range of 3,000 to 200,000, preferably in the range of 4,000 to 150,000, and more preferably in the range of 5,000 to 100,000.

### (Catalyst)

In the embodiment, when the polymer (C1) is adjusted, in order to accelerate the hydrolyzation and condensation reaction between the silane compound (c1) and the specific silyl group-containing vinyl-based polymer (c2), a catalyst is preferably added to the silane compound (c1). The degree of crosslinking of the obtained polymer (C1) can be increased by adding the catalyst, the molecular weight of the polysiloxane generated by the polycondensation reaction of the organosilane (2) increases, and as a result, a cured body having excellent strength, long term durability, or the like can be obtained.

Examples of the catalyst used for accelerating this hydrolyzation and condensation reaction include a basic compound, an acidic compound, a salt compound, and an organic metal compound.

### (Basic Compound)

Examples of the basic compound include ammonia (including ammonia aqueous solution), an organic amine compound, a hydroxide of an alkali metal or an alkali earth metal such as sodium hydroxide and potassium hydroxide, and an alkoxide of an alkali metal such as sodium methoxide and sodium ethoxide. Among them, ammonia and the organic amine compound are preferable.

Examples of the organic amine include an alkylamine, an alkoxyamine, an alkanolamine, and an arylamine.

Examples of the alkylamine include an alkylamine having a 1-4C alkyl group such as methylamine, ethylamine, propylamine, butylamine, hexylamine, octylamine, N,N-dimethylamine, N,N-diethylamine, N,N-dipropylamine, N,N-dibutylamine, trimethylamine, triethylamine, tripropylamine, and tributylamine.

Examples of the alkoxyamine include an alkoxyamine having a 1-4C alkoxy group such as methoxymethylamine, methoxyethylamine, methoxypropylamine, methoxybutylamine, ethoxymethylamine, ethoxyethylamine, ethoxypropylamine, ethoxybutylamine, propoxymethylamine, propoxyethylamine, propoxypropylamine, propoxybutylamine, butoxymethylamine, butoxyethylamine, butoxypropylamine, and butoxybutylamine.

Examples of the alkanolamine include an alkanolamine having a 1-4C alkyl group such as methanolamine, ethanolamine, propanolamine, butanolamine, N-methylmethanolamine, N-ethylmethanolamine, N-propylmethanolamine, N-butylmethanolamine, N-methylethanolamine, N-propylethanolamine, N-butylethanolamine, N-methylpropanolamine, N-ethylpropanolamine, N-propylpropanolamine, N-butylpropanolamine, N-methylbutanolamine, N-ethylbutanolamine, N-propylbutanolamine, N-butylbutanolamine, N,N-dimethylmethanolamine, N,N-diethylmethanolamine, N,N-dipropylmethanolamine, N,N-dibutylmethanolamine, N,N-dimethylethanolamine, N,N-diethylethanolamine, N,N-dipropylethanolamine, N,N-dibutylethanolamine, N,N-dimethylpropanolamine, N,N-diethylpropanolamine, N,N-dipropylpropanolamine, N,N-dibutylpropanolamine, N,N-dimethylbutanolamine, N,N-diethylbutanolamine, N,N-dipropylbutanolamine, N,N-dibutylbutanolamine, N-methyldimethanolamine, N-ethyldimethanolamine, N-propyldimethanolamine, N-butyldimethanolamine, N-methyldiethanolamine, N-ethyldiethanolamine, N-propyldiethanolamine, N-butyldiethanolamine, N-methyldipropanolamine, N-ethyldipropanolamine, N-propyldipropanolamine, N-butyldipropanolamine, N-methyldibutanolamine, N-ethyldibutanolamine, N-propyldibutanolamine, N-butyldibutanolamine, N-(aminomethyl)methanolamine, N-(aminomethyl)ethanolamine, N-(aminomethyl)propanolamine, N-(aminomethyl)butanolamine, N-(aminoethyl)methanolamine, N-(aminoethyl) ethanolamine, N-(aminoethyl)propanolamine, N-(aminoethyl)butanolamine, N-(aminopropyl)methanolamine, N-(aminopropyl)ethanolamine, N-(aminopropyl)propanolamine, N-(aminopropyl)butanolamine, N-(aminobutyl)methanolamine, N-(aminobutyl) ethanolamine, N-(aminobutyl)propanolamine, and N-(aminobutyl)butanolamine.

Examples of the arylamine include aniline and N-methylaniline.

Further, examples of an organic amine other than the above include a tetraalkylammonium hydroxide such as tetramethylammonium hydroxide, tetraethylammonium hydroxide, tetrapropylammonium hydroxide, and tetrabutylammonium hydroxide; a tetraalkyl ethylenediamine such as tetramethyl ethylenediamine, tetraethyl ethylenediamine, tetrapropyl ethylenediamine, and tetrabutyl ethylenediamine; an alkylaminoalkylamine such as methylaminomethylamine, methylaminoethylamine, methylaminopropylamine, methylaminobutylamine, ethylaminomethylamine, ethylaminoethylamine, ethylaminopropylamine, ethylaminobutylamine, propylaminomethylamine, propylaminoethylamine, propylaminopropylamine, propylaminobutylamine, butylaminomethylamine, butylaminoethylamine, butylaminopropylamine, and butylaminobutylamine; a polyamine such as ethylenediamine, hexamethylenediamine, diethylenetriamine, triethylenetetramine, tetraethylenepentamine, m-phenylenediamine, and p-phenylenediamine; pyridine, pyrrole, piperazine, pyrrolidine, piperidine, picoline, morpholine, methylmorpholine, diazabicyclooctane, diazabicyclononane, and diazabicycloundecene.

The basic compounds may be used singly, or two or more types thereof may be used in mixture. Among them, triethylamine, tetramethylammonium hydroxide, and pyridine are particularly preferable.

### (Acidic Compound)

As the acidic compound, organic acid and inorganic acid are included. Examples of the organic acid include acetic acid, propionic acid, butanoic acid, pentanoic acid, hexanoic acid, heptanoic acid, octanoic acid, nonanoic acid, decanoic acid, oxalic acid, maleic acid, maleic anhydride, methylmalonic acid, adipic acid, sebacic acid, gallic acid, butyric acid, mellitic acid, arachidonic acid, shimic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, methanesulfonic acid, phthalic acid, fumaric acid, citric acid, and tartaric acid. Examples of the inorganic acid include hydrochloric acid, nitric acid, sulfuric acid, hydrofluoric acid, and phosphoric acid.

The acidic compounds may be used singly, or two or more types thereof may be used in mixture. Among them, maleic acid, maleic anhydride, methanesulfonic acid, and acetic acid are particularly preferable.

### (Salt Compound)

Examples of the salt compound include alkali metal salts of naphthenic acid, octylic acid, nitrous acid, sulfurous acid, aluminic acid, and carbonic acid.

### (Organic Metal Compound)

The organic metal compound includes an organic metal compound and/or a partial hydrolysate thereof (hereinafter, an organic metal compound and/or a partial hydrolysate thereof are collectively referred to as “organic metal compounds”).

Examples of the organic metal compounds include a compound (hereinafter, referred to as “organic metal compound (c)”) expressed by Expression (c) below,

M²(OR¹⁴)ₖ(R¹⁵COCHCOR¹⁶)₁ (c)

(in the expression, M² represents at least one metal atom selected from the group consisting of zirconium, titanium, and aluminum, R¹⁴ and R¹⁶ each independently represent a 1-6C univalent hydrocarbon group such as a methyl group, an ethyl group, an n-propyl group, an i-propyl group, an n-butyl group, a sec-butyl group, a t-butyl group, an n-pentyl group, an n-hexyl group, a cyclohexyl group, and a phenyl group, R¹⁶ represents the 1-6C univalent hydrocarbon group, or a 1-16C alkoxy group such as a methoxy group, an ethoxy group, an n-propoxy group, an i-propoxy group, an n-butoxy group, a sec-butoxy group, a t-butoxy group, a lauryloxy group, and a stearyloxy group, k and l each independently represent an integer of 0 to 4, and a relationship of (k+1)=(atom value of M²) is satisfied.), a tetravalent tin organic metal compound (hereinafter, referred to as “organic tin compound”) in which one or two 1-10C alkyl groups are bonded to one tin atom, or a partial hydrolysate thereof.

In addition, examples of the organic metal compounds include titanium alcoholates including a tetraalkoxy titanium such as tetramethoxy titanium, tetraethoxy titanium, tetra-i-propoxy titanium, and tetra-n-butoxy titanium; a trialkoxy titanium such as methyltrimethoxy titanium, ethyltriethoxy titanium, n-propyltrimethoxy titanium, i-propyltriethoxy titanium, n-hexyltrimethoxy titanium, cyclohexyltriethoxy titanium, phenyltrimethoxy titanium, 3-chloropropyltriethoxy titanium, 3-aminopropyltrimethoxy titanium, 3-aminopropyltriethoxy titanium, 3-(2-aminoethyl)-aminopropyltrimethoxy titanium, 3-(2-aminoethyl)-aminopropyltriethoxy titanium, 3-(2-aminoethyl)-aminopropylmethyldimethoxy titanium, 3-anilinopropyltrimethoxy titanium, 3-mercaptopropyltriethoxy titanium, 3-isocyanatepropyltrimethoxy titanium, 3-glycidoxypropyltriethoxy titanium, and 3-ureidopropyltrimethoxy titanium; and a dialkoxy titanium such as dimethyldiethoxy titanium, diethyldiethoxy titanium, di-n-propyldimethoxy titanium, di-i-propyldiethoxy titanium, di-n-pentyldimethoxy titanium, di-n-octyldiethoxy titanium, di-n-cyclohexyldimethoxy titanium, and diphenyldimethoxy titanium, and condensates thereof.

Examples of the organic metal compound (c) include an organic zirconium compound such as tetra-n-butoxy zirconium, tri-n-butoxy.ethyl acetoacetate zirconium, di-n-butoxy.bis(ethyl acetoacetate) zirconium, n-butoxy.tris(ethyl acetoacetate) zirconium, tetrakis(n-propyl acetoacetate) zirconium, tetrakis(acetyl acetoacetate) zirconium, tetrakis(ethyl acetoacetate)zirconium, and di-n-butoxy.bis(acetylacetonate)zirconium;

an organic titanium compound such as tetra-i-propoxy titanium, di-i-propoxy.bis(ethyl acetoacetate) titanium, di-i-propoxy.bis(acetylacetate)titanium, and di-i-propoxy.bis(acetylacetone)titanium; and

an organic aluminum compound such as tri-i-propoxy aluminum, di-i-propoxy.ethyl acetoacetate aluminum, di-i-propoxy.acetylacetonate aluminum, i-propoxy.bis(ethyl acetoacetate)aluminum, i-propoxy.bis(acetylacetonate)aluminum, tris(ethyl acetoacetate)aluminum, tris(acetylacetonate)aluminum, and monoacetylacetonate.bis(ethyl acetoacetate)aluminum.

Examples of the organic tin compound include a carboxylic acid-type organic tin compound such as

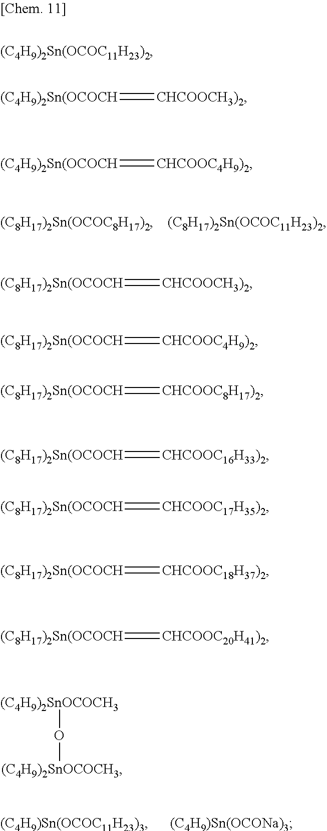

a mercaptide-type organic tin compound such as

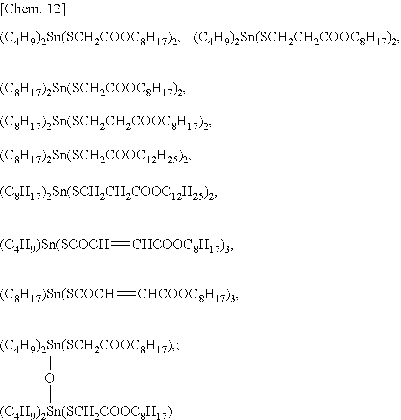

a sulfide-type organic tin compound such as

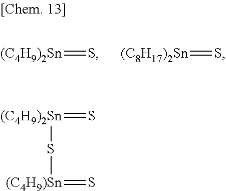

a chloride-type organic tin compound such as

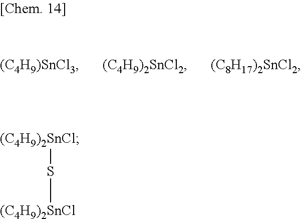

an organic tin oxide such as (C₄H₉)₂SnO, (C₈H₁₇)₂SnO, and reaction products of the organic tin oxide with an ester compound such as silicate, dimethyl maleate, diethyl maleate, and dioctyl phthalate.

The organic metal compounds may be used singly, or two or more types thereof may be used in mixture. Among them, di-n-butoxy.bis (acetylacetonate)zirconium, dioctyltin.dioctyl maleate, di-i-propoxy.bis (acetylacetonate) titanium, di-i-propoxy.ethyl acetoacetate aluminum, and tris(ethyl acetoacetate)aluminum, or a partial hydrolysate thereof is preferable.

In addition, the catalyst may be used in mixture with a zinc compound or other reaction retardants.

If the catalyst is not the organic metal compounds, the used amount of the catalyst is generally in the range of 0.001 part by weight to 100 parts by weight, preferably in the range of 0.01 part by weight to 80 parts by weight, and more preferably in the range of 0.1 part by weight to 50 parts by weight with respect to 100 parts by weight of the silane compound (c1) (in terms of completely hydrolyzed and condensed product of the organosilane (2)). If the catalyst is the organic metal compounds, the used amount of the catalyst is generally 100 parts by weight or less, preferably in the range of 0.1 part by weight to 80 parts by weight, and more preferably in the range of 0.5 parts by weight to 50 parts by weight with respect to 100 parts by weight of the silane compound (c1) (in terms of completely hydrolyzed and condensed product of the organosilane (2)). If the used amount of the catalyst is greater than the upper limit, the preservation stability of the polymer (C1) is decreased to causing the polymer (C1) to be a gel, or the degree of crosslinking of the second layer increases to generate cracks.

### (Water)

According to the embodiment, it is preferable that water is added to the silane compound (c1), and the polymer (C1) is prepared by the condensation reaction of the silane compound (c1).

The added amount of water at this point is generally 0.1 mol to 1.0 mol, preferably in the range of 0.2 mol to 0.8 mol, and more preferably in the range of 0.25 mol to 0.6 mol with respect to 1 mol of all OR⁴ groups in the silane compound (c1). If the added amount of water is in the range described above, the gelation hardly occurs, and the composition shows satisfactory preservation stability. In addition, the added amount of water is in the range described above, sufficiently crosslinked polymer (C1) can be obtained, and thus the second layer can be obtained with the polymer (C1).

### (Organic Solvent)

According to the embodiment, the hydrolyzation and condensation reaction of the silane compound (c1) may be performed in the organic solvent. The used solvent is not particularly limited, as long as it can be used in the hydrolyzation and condensation reaction of the silane compound (c1), and the examples thereof include alcohols, aromatic hydrocarbons, ethers, ketones, and esters. Examples of the alcohols include methanol, ethanol, n-propyl alcohol, i-propyl alcohol, n-butyl alcohol, sec-butyl alcohol, t-butyl alcohol, isobutyl alcohol, n-hexyl alcohol, n-octyl alcohol, ethylene glycol, diethylene glycol, triethylene glycol, ethylene glycol monobutyl ether, ethylene glycol monoethyl ether acetate, diethylene glycol monoethyl ether, propylene glycol monomethyl ether, propylene monomethyl ether acetate, and diacetone alcohol.

In addition, examples of the aromatic hydrocarbons include benzene, toluene, and xylene, examples of ethers include tetrahydrofuran and dioxane, examples of ketones include acetone, methyl ethyl ketone, methylisobutyl ketone, and diisobutyl ketone, and examples of esters include ethyl acetate, propyl acetate, butyl acetate, carbonated propylene, methyl lactate, ethyl lactate, n-propyl lactate, isopropyl lactate, methyl 3-ethoxypropionate, and ethyl 3-ethoxypropionate. The organic solvents may be used singly, or two or more types thereof may be used in mixture.

In addition, in order to adjust a solid content concentration at the time of preparing the polymer (C1), an organic solvent can be added, if necessary. Further, the organic solvent used at the time of the hydrolyzation and condensation reaction of the silane compound (c1) may be removed, and an organic solvent may be newly added.

The organic solvent in an amount preferably in the range of 10% by weight to 80% by weight, more preferably in the range of 15% by weight to 60% by weight, and particularly preferably in the range of 20% by weight to 50% by weight can be added in terms of the solid content concentration at the time of preparing the polymer (C1). In addition, if the organic solvent used at the time of preparing the silane compound (c1) is used as it is and the solid content concentration at the time of preparing the polymer (C1) is in the range described above, the organic solvent may be added or may not be added.

The reactivity of the silane compound (c1) can be controlled by adjusting the solid content concentration at the time of preparing the polymer (C). If the solid content concentration at the time of preparing the polymer (C1) is less than the lower limit described above, the reactivity of the silane compound (a1) may be decreased. If the solid content concentration at the time of preparing the polymer (C1) is greater than the upper limit, the gelation may occur. In addition, the solid content amount in the solid content concentration is a total amount of the used amount (Wc1) of the silane compound (c1) in terms of the completely hydrolyzed and condensed product.

### (Stabilization Improving Agent)

According to the embodiment, in order to improve the preservation stability of the polymer (C1), it is preferable to add the stabilization improving agent after the polymer (C1) is prepared, if necessary. The stabilization improving agent used in the embodiment is at least one compound selected from the group consisting of β-diketones, β-ketoesters, a carboxylic acid compound, a dihydroxy compound, an amine compound and an oxyaldehyde compound expressed by Expression (d) below.

R¹⁷COCH₂COR¹⁸ (d)

(in the expression, R¹⁷ represents a 1-6C univalent hydrocarbon group such as a methyl group, an ethyl group, an n-propyl group, an i-propyl group, an n-butyl group, a sec-butyl group, a t-butyl group, an n-pentyl group, an n-hexyl group, a cyclohexyl group, and a phenyl group, and R¹⁸ represents the 1-6C univalent hydrocarbon group, or a 1-16C alkoxyl group such as a methoxy group, an ethoxy group, an n-propoxy group, an i-propoxy group, an n-butoxy group, a sec-butoxy group, a t-butoxy group, a lauryloxy group, and a stearyloxy group.)

When the organic metal compounds are used as the catalyst, the stabilization improving agent expressed by Expression (d) above is preferably added. If the stabilization improving agent is used, the stabilization improving agent is coordinated with a metal atom of the organic metal compounds, and thus it is considered that the coordination suppresses the excessive condensation reaction of the silane compound (c1), and further improves the preservation stability of the obtained polymer (C1).

Examples of the stabilization improving agents include acetylacetone, methyl acetoacetate, ethyl acetoacetate, n-propyl acetoacetate, i-propyl acetoacetate, n-butyl acetoacetate, sec-butyl acetoacetate, t-butyl acetoacetate, hexane-2,4-dione, heptane-2,4-dione, heptane-3,5-dione, octane-2,4-dione, nonane-2,4-dione, 5-methylhexane-2,4-dione, malonic acid, oxalic acid, phthalic acid, glycolic acid, salicylic acid, aminoacetic acid, iminoacetic acid, ethylenediaminetetraacetic acid, glycol, catechol, ethylenediamine, 2,2-bipyridine, 1,10-phenanthroline, diethylenetriamine, 2-ethanolamine, dimethylglyoxime, dithizone, methionine, and salicylaldehyde. Among them, acetylacetone and ethyl acetoacetate are preferable.

In addition, the stabilization improving agents may be used singly, or two or more types thereof may be used in mixture.

The amount of stabilization improving agent used in the embodiment is generally 2 mol or more, and preferably in the range of 3 mol to 20 mol with respect to 1 mol of the organic metal compound of the organic metal compounds. If the amount of the stabilization improving agent is less than the lower limit, the effect of improving the preservation stability of the obtained composition may be insufficient.

The weight average molecular weight of the polymer (C1) obtained by the methods described above as a value in terms of polystyrene which is measured by the gel permeation chromatography is generally in the range of 3,000 to 200,000, preferably in the range of 4,000 to 150,000, and more preferably in the range of 5,000 to 100,000.

### (Silica Particles (D))

The silica particles (D) may be combined with the composition (II) to be used. The silica particles (D) may be used in the form of powder, or a solvent-based sol or colloid dispersed in a polar solvent such as methanol or in a nonpolar solvent such as toluene. In addition, in order to improve the dispersibility of the silica particles (D), a surface treatment may be performed to be used.

The silica particles (D) can be classified into dry silica and wet silica. A typical method of manufacturing dry silica is a combustion method in which silicon tetrachloride and hydrogen are mixed and combusted in a gas phase at 1,000° C. or higher. Meanwhile, the wet silica can be basically obtained by reacting sodium silicate and acid in an aqueous liquid. According to the embodiment, any silica particles of dry silica and wet silica can be used. According to the combination of the silica particles (D), the strength of the second layer obtainable from the composition (II) is improved, and the generation of cracks or the like can be avoided.

The primary particle size of the silica particles (D) is generally 0.0001 μm to 1 μm, more preferably in the range of 0.001 μm to 0.5 μm, and particularly preferably in the range of 0.002 μm to 0.2 μm.

In the case of a silica particle solvent-based sol or colloid, the solid content concentration is generally greater than 0% by weight and 50% by weight or less, and preferably in the range of 0.01% by weight to 40% by weight.

According to the embodiment, examples of the powdered silica which is not subjected to the surface treatment include #150, #200, and #300 manufactured by Nippon Aerosil Co., Ltd., OK520 manufactured by Evonik Industries AG, and Sylysia 350 and Sylysia 430 manufactured by Fuji Silysia Chemical Ltd., and examples of powdered silica subjected to hydrophobization treatment include R972, R974, R976, RX200, RX300, RY200S, RY300, R106 manufactured by Nippon Aerosil Co., Ltd., SS50A manufactured by Tosoh Corporation, and Sylophobic 100 and Sylophobic 200 manufactured by Fuji Silysia Chemical Ltd.

In addition, examples of the solvent dispersed colloidal silica include a solvent dispersed colloidal silica based on alcohols such as methanol and isopropyl alcohol, a solvent dispersed colloidal silica based on a ketone such as methylisobutyl ketone, and a solvent dispersed colloidal silica based on a nonpolar solvent such as toluene, manufactured by Nissan Chemical Industries, Ltd. The silica particles (D) may be added at the time of preparing the silane compound (c1), or after the preparation.

When the solvent dispersed colloidal silica is used, the dispersion of the silica particles (D) may be performed in a solution system by using a stirring blade or the like, but when powder silica is used, a well-known disperser such as a ball mill, a sand mill (bead mill or high shear bead mill), a homogenizer, an ultrasonic homogenizer, a nanomizer, a propeller mixer, a high shear mixer, a paint shaker, a planetary mixer, a twin roll, a triple roll, and a kneader roll can be used, and particularly, a highly dispersed fine particle dispersed body ball mill, a sand mill (bead mill, high shear bead mill), and a paint shaker are preferably used.

The used amount of the silica particles (D) is generally greater than 0% by weight and 80% by weight or less, and preferably in the range of 5% by weight to 50% by weight in terms of the solid content with respect to the solid content of the silane compound (c1).

### (Curing Catalyst)

The curing catalyst is further added to the composition (II) used in the embodiment. Examples of the curing catalyst include a basic compound, an acidic compound, a salt compound, and an organic metal compound used at the time of preparing the polymer (C1). The basic compounds may be used singly, or two or more types thereof may be used in mixture, and triethylamine, tetramethylammonium hydroxide, and pyridine are particularly preferable. The acidic compounds may be used singly, and two or more types thereof may be used in mixture, and maleic acid, maleic anhydride, methanesulfonic acid, and acetic acid are particularly preferable. The organic metal compounds may be used singly, or two or more types thereof may be used in mixture, and di-n-butoxy.bis(acetylacetonate)zirconium, dioctyltin.dioctyl maleate, di-i-propoxy.bis(acetylacetonate)titanium, di-i-propoxy.ethyl acetoacetate aluminum, and tris(ethyl acetoacetate)aluminum, or a partial hydrolysate thereof is preferable.

### (Organic Solvent and Water)

The solid content concentration may be adjusted by adding the organic solvent or water to the composition (II) used in the embodiment. As the organic solvent, products exemplified in the section of the preparation of the polymer (C1) can be used.

### (Arbitrary Addition Component)

A leveling agent, a wettability modifying agent, a surfactant, a plasticizer, an ultraviolet light absorber, an antioxidant, an antistatic agent, a silane coupling agent, and an inorganic filler can be added to the composition (II) used in the embodiment, if necessary.

### (3-2) Method of Preparing Composition (II)

The composition (II) used in the embodiment can be obtained by adding the silica particles (D) to the silane compound (c1) and/or the polymer (C1), if necessary, and performing the dispersion process. In the dispersion process, (i) if the solvent-based sol or colloid is used as the silica particles (D), a method of using a stirring blade or the like can be used, and (ii) if powder particles are used, a method of using a ball mill, a bead mill, a paint shaker, and the like can be used. The organic solvent, water, a stabilization improving agent, a curing catalyst, and an arbitrary addition component can be added to the composition (II), if necessary, and these can be added before the dispersion process is performed, or can be added after the dispersion process is performed.

(3-3) Method of Forming a Film with the Composition (II)

The composition (II) used in the embodiment is applied on the first layer formed on the glass substrate, and is heated and dried to be used. The second layer has a lower refractive index than the first layer, and antireflection properties can be given by forming the laminated body. The coating method of the composition (II) is not particularly limited, but a method of using paint brush coating, brush coating, a bar coater, a knife coater, a doctor blade, screen printing, spray coating, a spin coater, an applicator, a roll coater, a flow coater, a centrifugal coater, an ultrasonic coater, a (micro)gravure coater, a dip coater, flexography, potting, and the like can be used, and the composition (II) may be used by being applied on other base materials (transferring base material) and be transferred.

The heating and drying is preferably performed by heating at a temperature in the range of 50° C. to 200° C. for a time in the range of 0.5 minutes to 180 minutes. For the heating and drying, a general oven is used, and a hot air-type oven, a convection-type oven, an infrared-type oven, and the like can be used. By the heating, the solvent is removed, the condensation reaction in the layer is progressed, and thus a stronger layer can be obtained. When the heating temperature is desirably high, and the heating time is desirably long, less of the solvent remains, and the condensation reaction is more progressed. In the heating process, the temperature may be increased in plural steps, or the heating may be performed by one step. According to the content, the boiling point, and the heating condition of the used solvent, the surface of an obtainable layer may be rough, and thus a proper heating process is desirably reviewed in advance.

### (4) Composition Kit for Forming Laminated Body

The kit formed with the composition (I) and the composition (II) can be used to form the laminated body according to the embodiment.

### (5) Laminated Body

The laminated body obtainable in the embodiment, that is, the laminated body formed with the glass substrate, the first layer, and the second layer has a siloxane structure as a main skeleton, and has more excellent heat resistance, light resistance, and weather resistance than the general organic polymer. In addition, since the laminated body can be manufactured by coating, the laminated body is more excellent in cost or in process than the method such as vacuum deposition or the like.

### (6) Transmittance of Laminated Body

The transmittance of the laminated body of the glass substrate, the first layer, and the second layer is set to be 82% or less at a wavelength of 340 nm. The transmittance of the laminated body may be 82% or less in the wavelength range of 340 nm or less. The transmittance of the laminated body at a wavelength of 340 nm or in the wavelength range of 340 nm or less is set to be preferably 81% or less. The lower limit value of the transmittance of the laminated body may be 0% or higher at a wavelength of 340 nm, or may be 0% or higher in the wavelength range of 340 nm or less.

The method of decreasing the transmittance of the laminated body at a wavelength of 340 nm is not particularly limited, and examples thereof include a method of changing film forming methods and/or film forming conditions of the first layer and the second layer or a method of blending an inorganic-based ultraviolet light absorber (for example, zinc oxide and titanium oxide) in the glass substrate.

### (7) Antireflective Film

The antireflective film is a film that can reduce the reflection on the surface. The kind and the performance of the antireflective film is not particularly limited, as long as the antireflective film contains an organic matter. Specific examples include an Anti Reflection (AR) film, a Low Reflection (LR) film having higher reflectivity than the AR film, and a moth eye film having particularly low reflectivity. As the antireflective film, a commercially available antireflection film can be used.

The antireflective film may have a base film containing an organic matter. Examples of the base film include a PET film and a TAC film. From the view point of improving a display quality of the display device, the TAC film is preferable as the base film. In addition, from the view point of keeping the display portion on the inner side from being deteriorated caused by the ultraviolet light and the view point of suppressing the yellowing of the base film itself, the ultraviolet light absorber is preferably blended in the base film. The transmittance of the base film with the ultraviolet light absorber may be 1% or less at 340 nm of the wavelength or in a wavelength range of 340 nm or less. The material of the ultraviolet light absorber blended in the base film is not particularly limited, and a general material can be used. Specifically, an inorganic ultraviolet light absorber (for example, zinc oxide and titanium oxide) can be used.

A method of manufacturing the antireflective film can be appropriately selected according to the kind thereof, but from the view point of cost reduction, the antireflective film is preferably manufactured by a coating method, and is preferably manufactured by coating the organic material on the base film. According to the embodiment, the weather resistance is not particularly required for the antireflective film, and the organic matter and the organic material may have a carbon-carbon bond (C—C bond).

The antireflective film is preferably pasted on the glass substrate by using a bonding agent or an adhesive agent. The usage of the bonding agent or the adhesive agent may be appropriately determined considering productivity. Generally, the bonding agent has strong bond strength, and the adhesive agent has weaker bond strength than the bonding agent. The materials of the bonding agent and the adhesive agent are not particularly limited, and examples thereof include an acryl-based material. According to the embodiment, since the yellowing of the antireflective film can be suppressed by adjusting the transmittance of the laminated body of the glass substrate, the first layer, and the second layer, the bonding agent and the adhesive agent do not both have to contain the ultraviolet light absorber. However, from the view point of particularly effectively keeping the antireflective film from yellowing, the bonding agent or the adhesive agent containing the ultraviolet light absorbers may be used. The materials of the ultraviolet light absorber blended in the bonding agent and the adhesive agent are not particularly limited, and a general material can be used. Specifically, an inorganic-based ultraviolet light absorber (for example, zinc oxide and titanium oxide) can be used. Each transmittance of the bonding agent and the adhesive agent may be 75% or higher and 80% or less at a wavelength of 340 nm or in the wavelength range of 340 nm or less.

### (8) Protective Plate

The protective plate obtained in the embodiment can be used as the antireflective member. The protective plate may be used indoors, and can be particularly preferably used as an antireflective member for various displays such as a cathode-ray tube display, a liquid crystal display, a plasma display, an organic EL display, or a rear projection display used in a solar cell, a car navigation, a cellular phone, video monitor, an information display, or the like used outdoors.

### (9) Display Device

As illustrated in FIG. 1, a display device 1 according to the embodiment includes a display portion 8 and the aforementioned protective plate 2 provided in front of the display portion 8. The protective plate 2 is arranged so that the antireflective film 6 is positioned between the display portion 8 and the laminated body 7. The protective plate 2 is arranged on the observer side of the screen of the display portion 8, that is, in front of the screen, and is arranged to cover the screen (display area) of the display portion 8.

As the display portion 8, for example, various displays such as a cathode-ray tube display, a liquid crystal display, a plasma display, an organic EL display, or a rear projection display can be used.

### (GPC Measurement)

The weight average molecular weight of siloxane was measured by gel permeation chromatography in the following condition, and was indicated as a value in terms of the polystyrene. Apparatus: HLC-8120C (manufactured by Tosoh Corporation), Column: TSK-gel Multipore HXL-M (manufactured by Tosoh Corporation), Eluent: THF, Flow rate: 0.5 mL/min, Load amount: 5.0%, 100 μL, Measurement temperature: 40° C.

### SYNTHESIZATION EXAMPLE

142 parts of methyltrimethoxysilane, 49 parts of dimethyldimethoxysilane, 763 parts of methylisobutyl ketone as solvent, 152 parts of water, and 19 parts of triethylamine as catalyst were mixed in a reaction vessel having a return current condenser and a stirrer, and the hydrolyzation and condensation reaction was performed at 60° C. for 3 hours. Cooling was performed to room temperature, 156 parts of 6% oxalic acid aqueous liquid was added, and the neutralization reaction was performed at room temperature for one hour. Thereafter, the water layer was removed, and the organic phase was washed with 150 parts of water. The water washing operation was performed three times, the solvent was distilled, and thus the polymer (1) having 20% by weight of the solid content concentration, and 8000 of the Mw in the GPC was obtained.

### Preparation Example 1

With respect to 100 parts of the polymer (1) liquid, 20 parts of zirconium oxide powder having 10 nm of a primary particle diameter, 80 parts of methylisobutyl ketone, and 0.01 part of triethylamine were added and dispersed for 4 hours with a paint shaker, and thus the hard coat composition (1) having 20% by weight of the solid content concentration was obtained.

### Preparation Example 2

With respect to 100 parts of the polymer (1) liquid, 20 parts of a methyl ethyl ketone dispersed silica sol having 30% by weight of the solid content concentration (manufactured by Nissan Chemical Industries, Ltd.) and 400 parts of methylisobutyl ketone were added and stirred for 1 hour with a three-one motor at room temperature, and thus the antireflective composition (1) having 5% by weight of solid content concentration was obtained.

### Example 1

FIG. 2 is a cross-sectional view schematically illustrating the protective plate of Example 1.

As illustrated in FIG. 2, the hard coat composition (1) was applied on the main surface (front surface) on one side of a soda glass plate 13 having a thickness of 0.7 mm by using a spin coater, and then the coated film was dried at 200° C. for 30 minutes, and thus a hard coat layer 14 in which zirconium oxide particles were mixed with polyorganosiloxane was formed as the first layer. Thereafter, the antireflective composition (1) diluted to a predetermined concentration was applied on the hard coat layer 14 by using a spin coater, and then the coated film was dried at 200° C. for 30 minutes, and thus an antireflective layer 15 in which silica particles are mixed with polyorganosiloxane was formed as the second layer. In this manner, the antireflective layer 15 was laminated on the hard coat layer 14, and thus protective glass 17 was manufactured as the laminated body.

Also, an antireflective film 16 was pasted on the main surface (rear surface) on the other side of the protective glass 17 via an adhesive agent (not illustrated), and thus a protective plate 12 of Example 1 was manufactured. As the adhesive agent, an adhesive film “Panaclean PD-S1” manufactured by Panac Co., Ltd. which has a thickness of 10 μm was used. Panaclean PD-S1 was an acryl-based adhesive agent, and the transmittance thereof was approximately 78% at a wavelength of 340 nm.

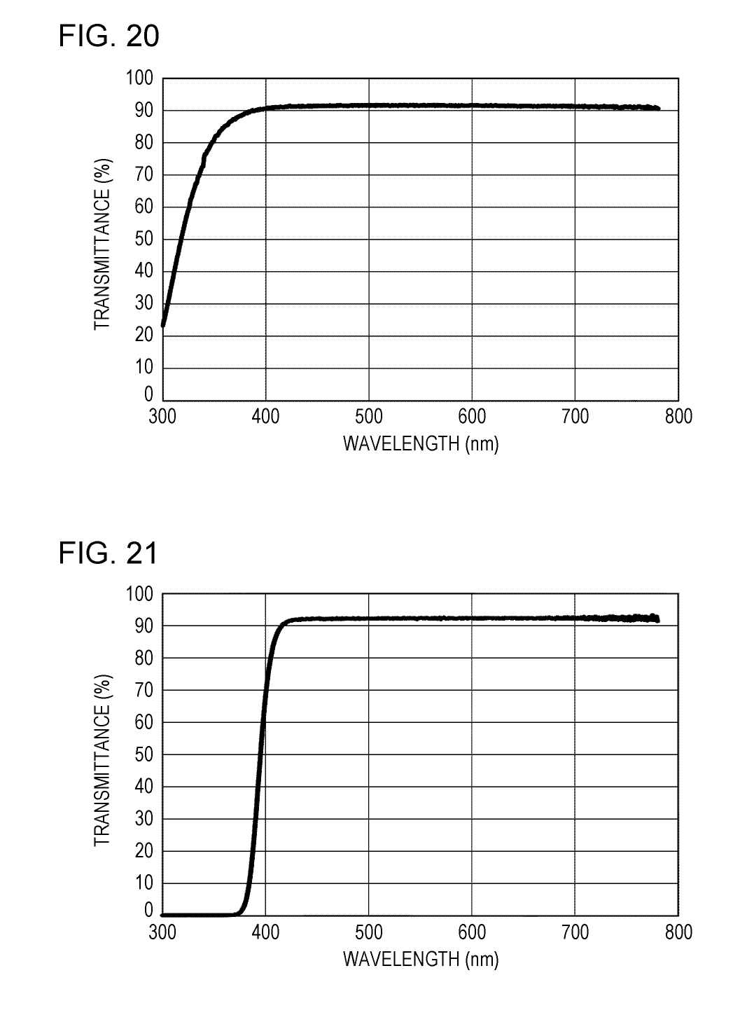

As the antireflective film 16, an antireflective film “DSG-03” manufactured by Dai Nippon Printing Co., Ltd. was used. The antireflective film “DSG-03” was an antireflective film obtained by coating an organic-based low refractive index layer on a TAC film with an ultraviolet light absorber. FIG. 19 is a graph illustrating transmittance of the antireflective film used in Example 1. As illustrated in FIG. 19, the antireflective film 16 used in Example 1 showed extremely little transmittance in the ultraviolet area. It was considered that this was because the ultraviolet light absorber in the TAC film and the organic-based low refractive index layer mainly absorbed ultraviolet light. FIG. 21 is a graph illustrating transmittance of the TAC film with the ultraviolet light absorber which is contained in the antireflective film used in Example 1, and Table 1 presents typical transmittance of the TAC film in the ultraviolet area. As a result, the transmittance of the TAC film was approximately 0.006% at a wavelength of 340 nm.

TABLE 1

| Wavelength (nm) | Transmittance (%) |
|---|---|
| 400 | 68.425 |
| 390 | 29.051 |
| 380 | 3.694 |
| 370 | 0.207 |
| 360 | 0.016 |
| 350 | 0.004 |
| 340 | 0.006 |
| 330 | 0.011 |
| 320 | 0.011 |
| 310 | 0.004 |
| 300 | 0.004 |

### Comparative Example 1

FIG. 3 is a cross-sectional view schematically illustrating a protective plate of Comparative Example 1.

As illustrated in FIG. 3, a protective glass 27 was manufactured by pasting an antireflective film 29 on the main surface (front surface) on one surface of a soda glass plate 23 having a thickness of 0.7 mm via an adhesive agent (not illustrated).

Also, a protective plate 22 of Comparative Example 1 was manufactured by pasting an antireflective film 26 on the main surface (rear surface) on the other side of the protective glass 27 via an adhesive agent (not illustrated). As the adhesive agent and the antireflective films 26 and 29, the same products described in Example 1 were used.

### Comparative Example 2

FIG. 4 is a cross-sectional view schematically illustrating a protective plate of Comparative Example 2.

As illustrated in FIG. 4, a soda glass plate 33 having a thickness of 0.7 mm was prepared. Also, a protective plate 32 of Comparative Example 2 was manufactured by pasting an antireflective film 36 on the rear surface of the soda glass plate 33 via an adhesive agent (not illustrated). As the adhesive agent and the antireflective film 36, the same products described in Example 1 were used.

### (Transmittance Measurement)

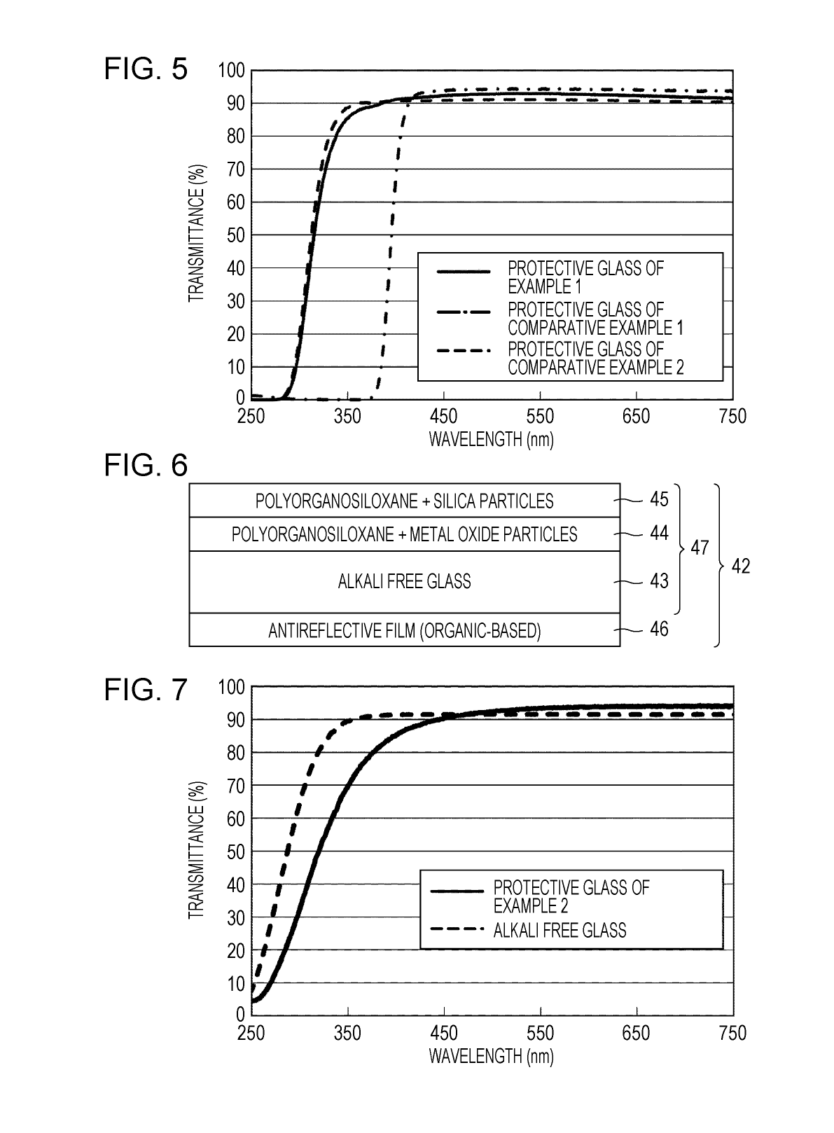

FIG. 5 is a graph illustrating transmittance of the protective glass used in Example 1 and Comparative Example 1 and transmittance of the soda glass plate used in Comparative Example 2.

The transmittance of the protective glass 17 used in Example 1, the transmittance of the protective glass 27 used in Comparative Example 1, and the transmittance of the soda glass plate 33 used in Comparative Example 2 were measured with a spectrophotometer “V-7100” manufactured by JASCO Corporation. As illustrated in FIG. 5, the protective glass 27 used in Comparative Example 1 showed little transmittance in the ultraviolet area, but it was considered that this was because the antireflective film 29 absorbed the ultraviolet light. More specifically, the transmittance of the protective glass 27 was approximately 0.02% at a wavelength of 340 nm.

On the other hand, the protective glass 17 used in Example 1 showed the same transmission spectrum as the soda glass plate 33, but the transmittance of the protective glass 17 was slightly lower than the transmittance of the soda glass plate 33 in the ultraviolet area. More specifically, the transmittance of the protective glass 17 and the soda glass plate 33 was approximately 81% and approximately 86% at a wavelength of 340 nm, respectively.

### Example 2

FIG. 6 is a cross-sectional view schematically illustrating the protective plate of Example 2.

As illustrated in FIG. 6, the hard coat composition (1) was applied on the main surface (front surface) on one side of an alkali free glass plate 43 having a thickness of 0.7 mm by using a spin coater, and then the coated film was dried at 200° C. for 30 minutes, and thus a hard coat layer 44 in which zirconium oxide particles were mixed with polyorganosiloxane was formed as the first layer. Thereafter, the antireflective composition (1) diluted to a predetermined concentration was applied on the hard coat layer 44 by using a spin coater, and then the coated film was dried at 200° C. for 30 minutes, and thus an antireflective layer 45 in which silica particles were mixed with polyorganosiloxane was formed as the second layer. In this manner, the antireflective layer 45 was laminated on the hard coat layer 44, and thus a protective glass 47 was manufactured as the laminated body.

Also, a protective plate 42 of Example 2 was manufactured by pasting an antireflective film 46 on the main surface (rear surface) on the other side of the protective glass 47 via an adhesive agent (not illustrated). As the adhesive agent and the antireflective film 46, the same products described in Example 1 were used.

### (Transmittance Measurement)

FIG. 7 is a graph illustrating the transmittance of the protective glass used in Example 2 and the transmittance of the alkali free glass plate used in Example 2.

The transmittance of the protective glass 47 used in Example 2 and transmittance of the alkali free glass plate 43 used in Example 2 were measured by spectrophotometer “V-7100” manufactured by Jasco Corporation. As illustrated in FIG. 7, the transmittance of the protective glass 47 used in Example 2 was lower than the transmittance of the alkali free glass plate 43 in the ultraviolet area. More specifically, the transmittance of the protective glass 47 was approximately 64% at a wavelength of 340 nm.

### (Ultraviolet Light Irradiation Test)

With respect to the protective plates of Examples 1 and 2 and Comparative Examples 1 and 2, an ultraviolet light irradiation test was performed by using Metal Weather “KW-R5TP” manufactured by Daipla Wintes Co., Ltd. The test condition was as follows.

Test condition: 63° C., 50% RH

Ultraviolet light luminance: 0.75 kW/m²

Test time: 100 hours and 200 hours

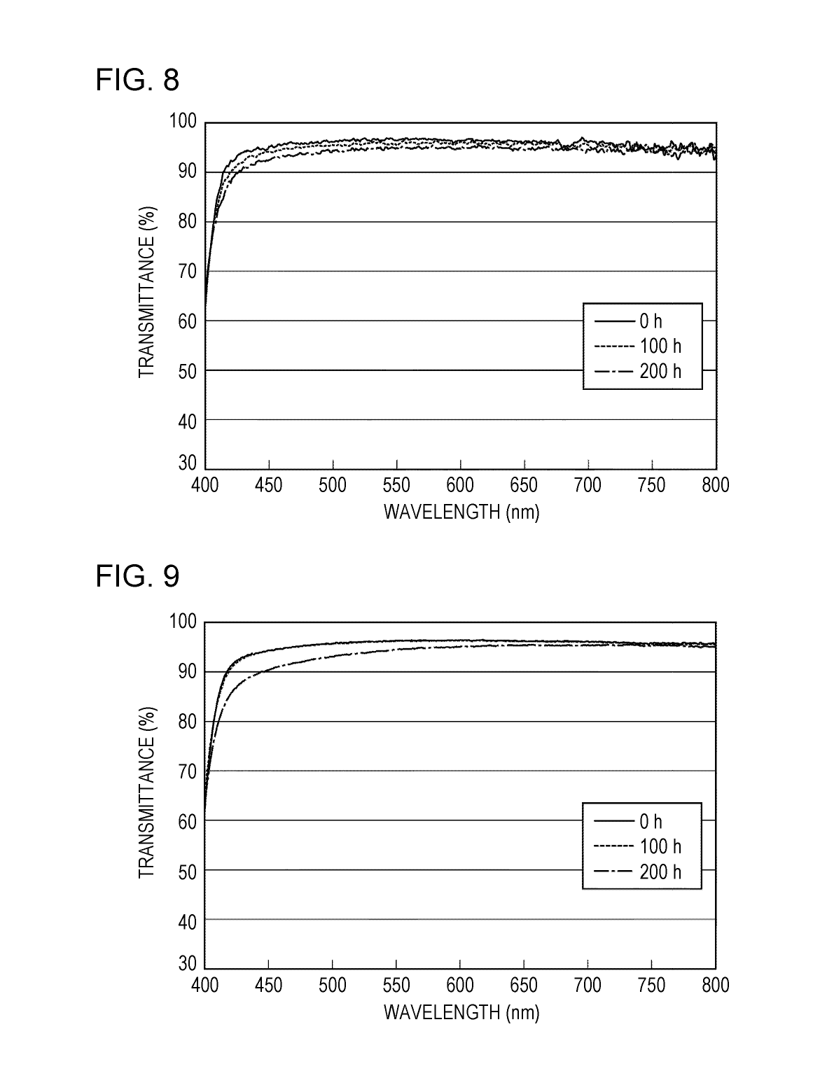

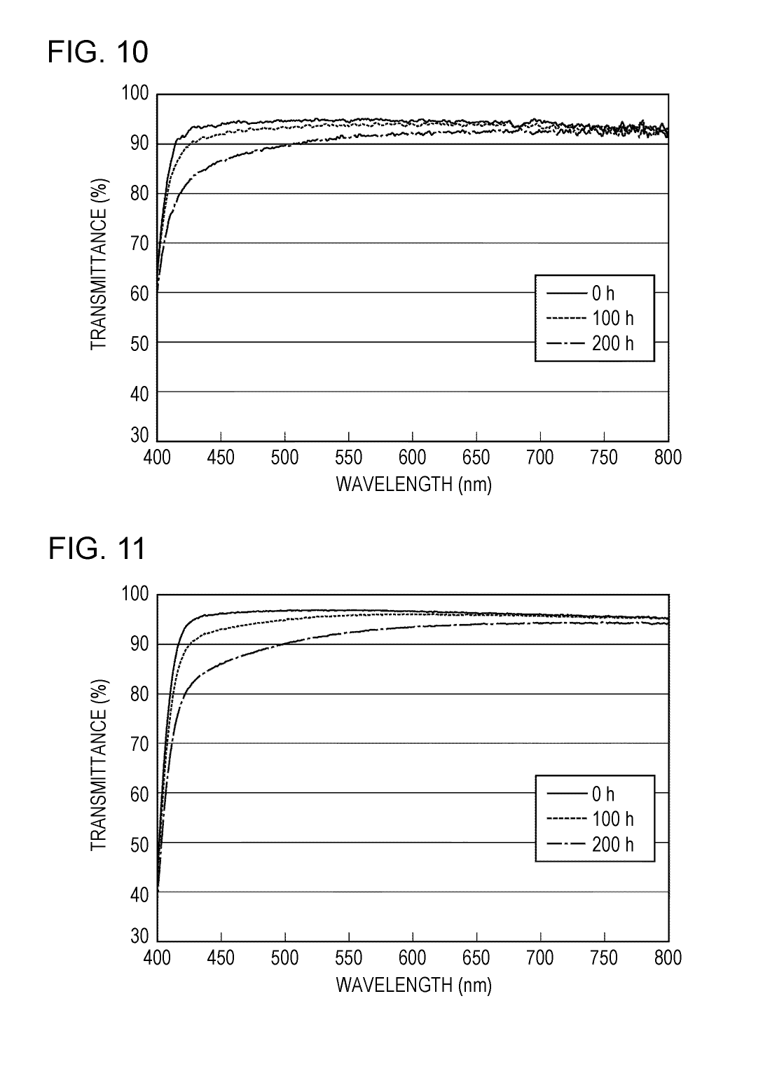

FIGS. 8 to 11 are graphs illustrating results obtained by measuring transmittance of the protective plate of Examples 1 and 2 and Comparative Examples 1 and 2 before and after the ultraviolet light irradiation tests. The test results were collectively presented in Table 2. In addition, whether the yellowing occurred was determined by visual observations.

TABLE 2

| | 100 Hours | 200 Hours |
|---|---|---|
| Example 1 | Yellowing didn't occur | Yellowing didn't occur |
| Example 2 | Yellowing didn't occur | Yellowing didn't occur |
| Comparative | Yellowing occurred | Yellowing occurred |
| Example 1 | | |
| Comparative | Yellowing didn't occur | Yellowing occurred |
| Example 2 | | |

As a result, yellowing didn't occur in the protective plates of Examples 1 and 2 even after 200 hours passed. In contrast, yellowing already occurred in the protective plate of Comparative Example 1 after 100 hours passed. In addition, in the protective plate of Comparative Example 2, yellowing didn't occur after 100 hours passed, but yellowing occurred after 200 hours passed. As a result of analyzing these protective plates, in Comparative Example 1, yellowing occurred in the antireflective film 29 on the front surface side, but yellowing did not occur in the antireflective film 26 on the rear surface side. In addition, in Comparative Example 2, yellowing occurred in the antireflective film 36 on the rear surface side. More specifically, in the antireflective film 36, yellowing rarely occurred in the TAC film with the ultraviolet light absorber, but yellowing mainly occurred in the organic-based low refractive index layer formed thereon. The TAC film with the ultraviolet light absorber was also the organic-based film, but it was considered that yellowing rarely occurred because the ultraviolet light absorber was present. In addition, in Comparative Example 2, yellowing rarely occurred in the adhesive agent between the antireflective film 36 and the protective glass 17.

From the above, it was found that yellowing didn't occur in the protective plates of Examples 1 and 2 and the antireflective film 26 on the rear surface side used in Comparative Example 1. According to this, if the transmittance of the members (for example, the protective glass 17, 27, and 47) arranged in front of the antireflective film on the rear surface side of the glass substrate is 82% or less (preferably, 81% or less) at a wavelength of 340 nm, it was found that the antireflective film on the rear surface side of the glass substrate was not deteriorated, and the occurrence of the yellowing was avoided.

FIG. 20 is a graph illustrating transmittance of the TAC film that does not contain an ultraviolet light absorber. As illustrated in FIG. 20, the absorbance of the light by the TAC film itself in the ultraviolet area was found. Accordingly, it was considered that yellowing would occur in a TAC film without an ultraviolet light absorber if the TAC film was irradiated with ultraviolet light.

Hereinafter, the reason of setting the maximum test time in the ultraviolet light irradiation test to be 200 hours is described.

First, since a durability period of an electronic apparatus such as a display which is regulated by the law is five years, 8 years of durability which is slightly longer than 5 years are enough for practical use. Also, it is considered that the ultraviolet light irradiation test for 200 hours corresponds to an outdoor test for 8 years. The basis thereof is as follows. The acceleration magnification of a light resistance test using a metal halide lamp used in Metal Weather is said to be approximately 100 times. If the acceleration magnification is estimated to be 90 times which is slightly lower than 100 times and calculation is performed, it is assumed that an outdoor test for

200 (hours)×90=18,000 (hours)

is performed. In addition, since the average of sunshine hours for the past 30 years in Yamanashi Prefecture which is one of the prefectures having the longest sunshine hours in Japan is 2,220 (hours/year),

18,000 (hours)/2,220 (hours/year)=8.1 (years)

is satisfied. The ultraviolet light irradiation test for 200 hours corresponds to an outdoor test in Yamanashi Prefecture for 8 years. From the above, if a product can endure an ultraviolet light irradiation test for 200 hours, the product can have sufficient weather resistance in Japan, for practical use.

Table 3 below presents results calculated by relationships between annual sunshine hours and durability periods corresponding to ultraviolet light irradiation tests for 200 hours. The durability periods were calculated by dividing 18,000 hours by annual sunshine hours. In addition, according to NPL 1, annual average sunshine hours of most cities in the world are within 3,000 hours. Accordingly, if a product can endure an ultraviolet light irradiation test for 200 hours, durability periods of 6 years or more can be secured in most cities in the world.

TABLE 3

| Annual sunshine hours | Durability period | |
|---|---|---|
| 1,500 hours | 12 | years |
| 2,000 hours | 9 | years |
| 2,500 hours | 7.2 | years |
| 3,000 hours | 6 | years |
| 3,500 hours | 5.1 | years |

### Example 3

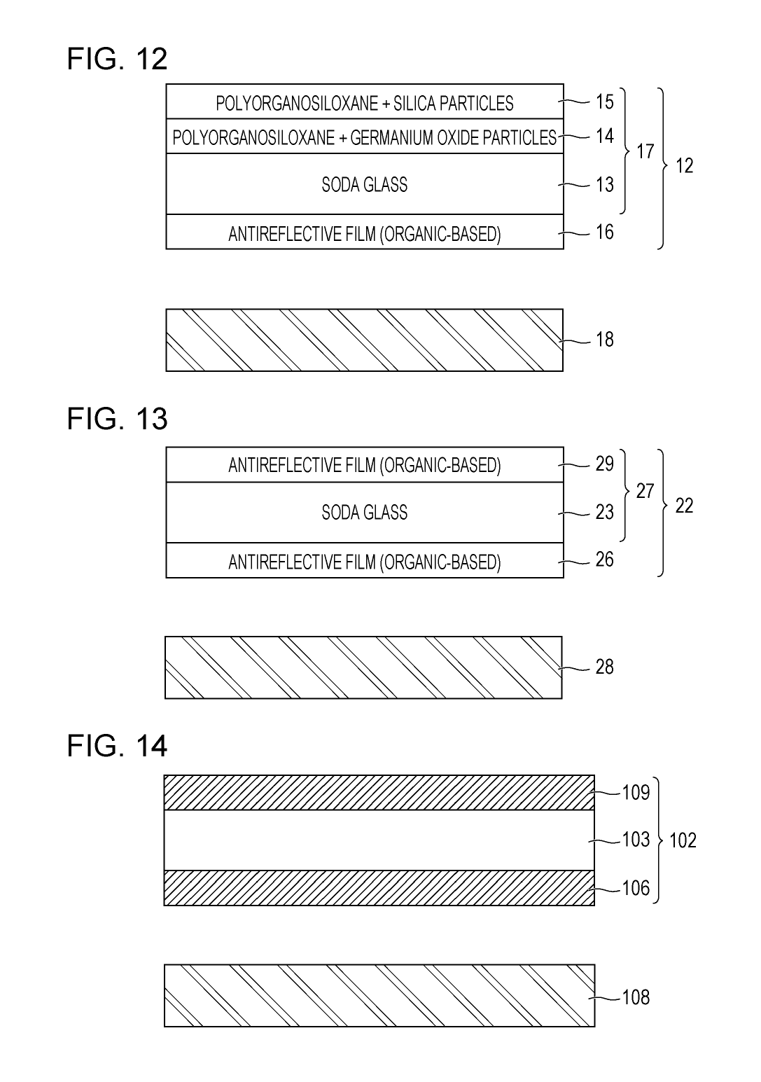

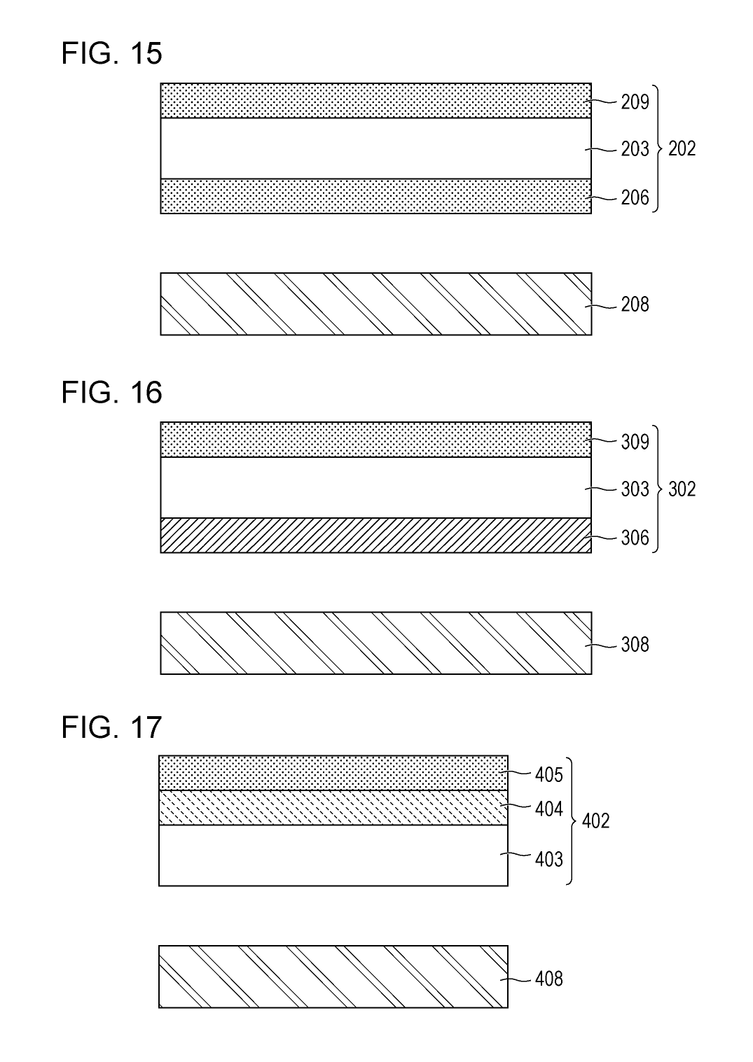

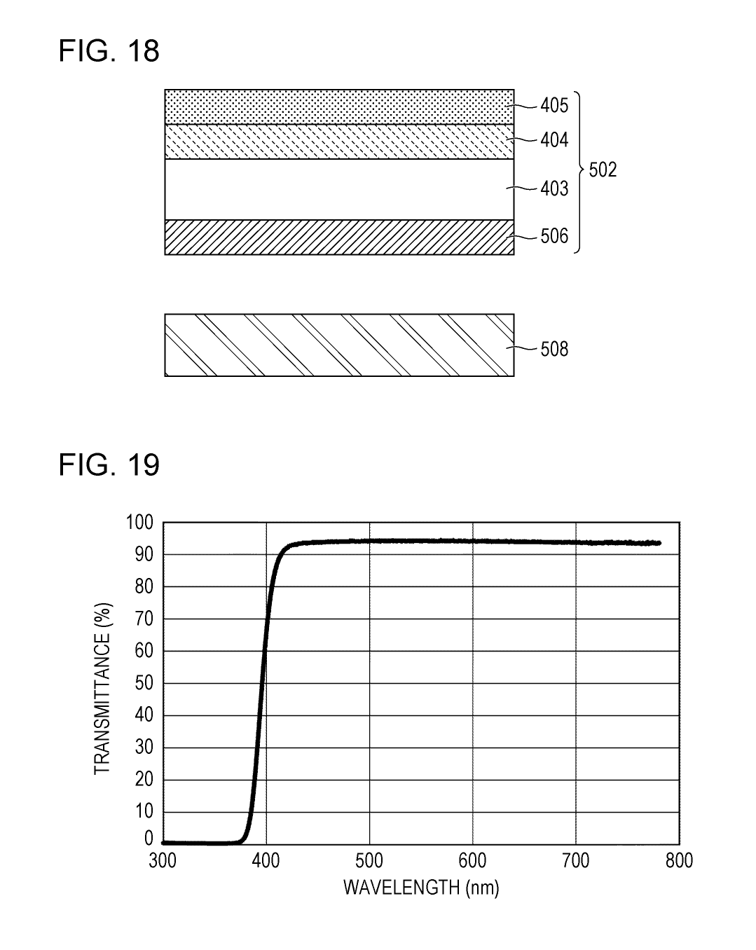

FIG. 12 is a cross-sectional view schematically illustrating a display device of Example 3.

As illustrated in FIG. 12, a liquid crystal display device of Example 3 was manufactured by arranging the protective plate 12 of Example 1 (which is not provided in an ultraviolet light irradiation test, however) in front of a liquid crystal display 18. As the liquid crystal display 18, a liquid crystal television “LC-40LV3” manufactured by Sharp Corporation was used.

### Example 4

Except for using the protective plate 12 of Example 1 which was subjected to the ultraviolet light irradiation test for 200 hours instead of using the protective plate 12 of Example 1 which was not provided in the ultraviolet light irradiation test, a liquid crystal display device of Example 4 was manufactured in the same manner as in Example 3.

### Comparative Example 3

FIG. 13 is a cross-sectional view schematically illustrating a display device of Comparative Example 3.

As illustrated in FIG. 13, a liquid crystal display device of Comparative Example 3 was manufactured by arranging the protective plate 22 of Comparative Example 1 (which was not provided in the ultraviolet light irradiation test, however) in front of a liquid crystal display 28. As the liquid crystal display 28, a liquid crystal television “LC-40LV3” manufactured by Sharp Corporation was used.

### Comparative Example 4

Except for using the protective plate 22 of Comparative Example 1 which was subjected to the ultraviolet light irradiation test for 200 hours instead of using the protective plate 22 of Comparative Example 1 which is not provided in the ultraviolet light irradiation test, a liquid crystal display device of Comparative Example 4 was manufactured in the same manner as in Comparative Example 3.

### (Visual Evaluation)

The visual evaluations of the manufactured liquid crystal display devices of Examples 3 and 4 and Comparative Examples 3 and 4 were performed. As a result, all of the display screens of the liquid crystal display devices of Examples 3 and 4 and Comparative Example 3 were recognizable without problems. On the contrary, the protective plate in the liquid crystal display device of Comparative Example 4 was colored to be yellow. Accordingly, overall displayed colors were turned yellow, and had a problem as a display.

### REFERENCE SIGNS LIST

1 DISPLAY DEVICE
2, 12, 22, 32, 42, 102, 202, 302, 402, 502 PROTECTIVE PLATE
3, 103, 203, 303, 403 GLASS SUBSTRATE
4 FIRST LAYER
5 SECOND LAYER
6, 16, 26, 29, 36, 46, 106, 109, 306, 506 ANTIREFLECTIVE FILM
7 LAMINATED BODY
8, 108, 208, 308, 408, 508 DISPLAY PORTION
13, 23, 33 SODA GLASS PLATE
14, 44, 404 HARD COAT LAYER
15, 45, 206, 209, 309, 405 ANTIREFLECTIVE LAYER
17, 27, 47 PROTECTIVE GLASS
18, 28 LIQUID CRYSTAL DISPLAY
43 ALKALI FREE GLASS PLATE

1. A protective plate comprising:
a glass substrate;
a first layer laminated on a main surface on one side of the glass substrate;
a second layer laminated on the first layer; and
an antireflective film pasted on a main surface on the other side of the glass substrate,
wherein the first layer contains polyorganosiloxane (A) and metal oxide particles (B),
wherein the second layer contains polyorganosiloxane (C),
wherein the antireflective film contains an organic matter, and
wherein transmittance of a laminated body of the glass substrate, the first layer, and the second layer is 82% or less at a wavelength of 340 nm.

2. The protective plate according to claim 1,
wherein the first layer is obtainable from a cured product of a composition (I),
wherein the composition (I) contains at least one kind of silane compound (a1) selected from the group consisting of at least one kind of organosilane expressed by Expression (1) below, a hydrolysate of the organosilane, and a condensate of the organosilane, and the metal oxide particles (B)
R¹ₙSi(OR²)₄₋ₙ (1)
(in the expression, R¹ represents a 1-8C univalent organic group, and if there are two R¹s, the R¹s may be the same with or different from each other, R² independently represents a 1-5C alkyl group or a 1-6C acyl group, n is an integer of 0 to 2),
wherein the second layer is obtainable from a cured product of a composition (II), and
wherein the composition (II) contains at least one kind of silane compound (c1) selected from the group consisting of at least one kind of organosilane expressed by Expression (2) below, a hydrolysate of the organosilane, and a condensate of the organosilane
R³ₘSi(OR⁴)₄₋ₘ (2)
(in the expression, R³ represents a 1-8C univalent organic group, if there are two R³s, the R³s may be the same with or different from each other, R⁴ independently represents a 1-5C alkyl group or a 1-6C acyl group, R⁴ is an integer of 0 to 2).

3. The protective plate according to claim 2,
wherein the composition (I) contains a polymer (A1) and the metal oxide particles (B), and
wherein the polymer (A1) is obtainable by performing hydrolysis and condensation on the silane compound (a1) and a vinyl-based polymer (a2) containing a silyl group having a silicon atom bonded to a hydrolyzable group and/or a hydroxyl group.

4. The protective plate according to claim 2,
wherein the composition (II) contains a polymer (C1), and
wherein the polymer (C1) is obtainable by performing hydrolysis and condensation on the silane compound (c1) and the vinyl-based polymer (c2) containing a silyl group having a silicon atom bonded to a hydrolyzable group and/or a hydroxyl group.

5. The protective plate according to claims 2,
wherein the composition (II) further contains silica particles (D).

6. The protective plate according to claims 1,
wherein the glass substrate contains soda glass or alkali free glass.

7. The protective plate according to claims 1,
wherein the antireflective film contains a TAC film.

8. The protective plate according to claim 1,
wherein the antireflective film contains a base film with an ultraviolet light absorber.

9. A display device comprising:
the protective plate according to claim 1.
